(19) United States
(12) Patent Application Publication
(10) Pub. No.: US 2011/0227081 A1
(43) Pub. Date: Sep. 22, 2011

(54) PIXEL CIRCUIT SUBSTRATE, DISPLAY DEVICE, ELECTRONIC EQUIPMENT, AND METHOD FOR MANUFACTURING PIXEL CIRCUIT SUBSTRATE

(75) Inventors: Kunihiro MATSUDA, Tokyo (JP); Hiroshi Matsumoto, Tokyo (JP); Yukikazu Tanaka, Tokyo (JP)

(73) Assignee: CASIO COMPUTER CO., LTD., Tokyo (JP)

(21) Appl. No.: 13/047,059

(22) Filed: Mar. 14, 2011

(30) Foreign Application Priority Data
Mar. 17, 2010 (JP) 2010-061647

(51) Int. Cl. H01L 33/16; H01L 33/08; H01L 33/36

(52) U.S. Cl. 257/59; 257/72; 438/34; 257/E33.053; 257/E33.004; 257/E33.003

(57) ABSTRACT

A pixel circuit substrate includes: a pixel electrode; a first drive element connected to one side of the pixel electrode; a second drive element that is connected to the first drive element in parallel and also is connected to the other side opposite to the one side of the pixel electrode.

### CROSS-REFERENCE TO RELATED APPLICATION

This application claims the benefit of Japanese Patent Application 2010-061647 filed Mar. 17, 2010, the entire disclosure of which is incorporated by reference herein.

### FIELD

This application relates to a pixel circuit substrate, a display device, an electronic equipment, and a method for manufacturing the pixel circuit substrate.

### BACKGROUND

Recently, as a next-generation display device following a liquid crystal display (LCD) device, a display device with a display-element-type display panel in which self-luminous elements, such as an organic electro luminescence element (hereinafter abbreviated as “organic EL (electro luminescence) element”), are arranged two-dimensionally in row and column directions, has increasingly been researched and developed for its full-scale practical application and widespread use.

An organic EL element includes an anode electrode, cathode electrode, and an organic thin-film layer (e.g. an electron injection layer, a luminescent layer, a hole injection layer) formed between these electrodes. The organic EL element is a display element that emits light by energy generated by recombination of a hole supplied from the hole injection layer and an electron supplied from the electron injection layer in a luminescent layer. This light is emitted by applying a voltage greater or equal to a predetermined voltage threshold on an organic thin-film layer, and a luminance of this light is controlled by the applied voltage. Such an organic EL element is used for a display device in various electronic equipments, as disclosed in Patent Literature 1, and is driven by a pixel drive circuit including, for example, a thin film transistor (TFT).

TFTs are divided into various shapes according to an arrangement of an electrode and a configuration of a film. For example, as illustrated in FIGS. 21A and 21B, there is an inversely staggered TFT in which a gate electrode 112 is covered with a gate insulating film 113 and disposed on a substrate 11, and a source electrode 118 and a drain electrode 119 are disposed above the gate electrode 112 with a semiconductor layer 114 being therebetween. As such a TFT, as illustrated in FIGS. 21A and 21B, known is, for example, a TFT in which an ohmic contact layer 120 for a low resistance connection lies between the source and drain electrodes 118, 119 and the semiconductor layer 114, and a channel protective film 115 is provided on the semiconductor layer 114 between the source and drain electrodes electrode 118, 119.

In the TFT having a channel protective film type structure illustrated in FIGS. 21A and 21B, the source and drain electrodes 118, 119 are formed so as to overlap the channel protective film 115 (see overlapping regions 116, 117 in FIG. 21B).

When the TFT having such a structure is formed for each luminescent pixel on the substrate 11 having a large area, positions of the source and drain electrodes 118, 119 formed may shift relative to the gate electrode 112 in a left and right (row direction) on a substrate surface, due to alignment deviation of a mask for laser irradiation in a lithography device or an exposure device (stepper) and warpage of the substrate 11, as illustrated in, for example, FIGS. 21C(i) and 21C(iii).

FIG. 21C(ii) illustrates a case where positions of the source and drain electrodes 118, 119 formed conform to a design and do not shift from desired positions. FIG. 21C(i) illustrates a case where positions of the source and drain electrodes 118, 119 formed shift rightward from their desired positions relative to the gate electrode 112 and channel protective film 115, that is, from the positions illustrated in FIG. 21C(ii). FIG. 21C(iii) illustrates the case where the positions of the source and drain electrodes 118, 119 formed shift leftward from their desired positions relative to the gate electrode 112 and channel protective film 115.

A difference between an area where the source electrode 118 overlaps the channel protective film 115 and an area where the drain electrode 119 overlaps the channel protective film 115 is defined by this position shift amount in the left and right direction. In other words, the degree of an effect of an electric field of the source electrode 118 on the channel protective film 115 and the degree of an effect of an electric field of the drain electrode 119 on the channel protective film 115 depend on the position shift amount. Therefore, if such a TFT is an n-channel type transistor, in the case illustrated in FIG. 21C(i), a channel current Ic[A] generally tends to be larger relative to an applied gate voltage Vg[V] as illustrated as a dash line in FIG. 22A, compared with the suitable case in FIG. 21C(ii) that is illustrated as a solid line in FIG. 22A. Meanwhile, in the case illustrated in FIG. 21C(iii), a channel current Ic[A] generally tends to be smaller relative to an applied gate voltage Vg[V] as illustrated as a dashed/dotted line in FIG. 22A, compared with the suitable case in FIG. 21C(ii) that is illustrated as a solid line in FIG. 22A.

FIG. 22B is a graph illustrating relationships between a current I(A) flowing from the drain to source and source to drain and a position shift amount (μm) in the left and right direction of the source and drain electrodes 118, 119 relative to the gate electrode 112 in FIGS. 21A and 21B, that is, a position shift amount (μm) when there is a position shift to the source side (the left side) or a position shift to the drain side (the right side) from a suitable position illustrated in FIG. 21C(ii). Especially in the case of the TFT having a channel protective film structure illustrated in FIGS. 21A and 21B, a difference between an area of the overlap region 116 where the source electrode 118 overlaps the channel protective film 115 and an area of the overlap region 117 where the drain electrode 119 overlaps the channel protective film 115, which is caused by a patterning position shift in the channel protective film 115 relative to its desired position and a patterning position shift in the source and drain electrodes 118, 119 relative to their desired positions, also depends on the shift amount.

As illustrated in FIG. 22B, when a position shift amount ΔX (μm) in the left and right direction of the source and drain electrodes 118, 119 relative to the channel protective film 115 is 0 μm, a current deviation amount (a percentage of an absolute value of a current deviation) between a current I (a.u.) and a reference current Is (a.u.) [=an absolute value of AI/Is×100%] is 0%. As an absolute value of a position shift amount to the drain side (the right side) ΔX is increasing, the degree of a current reduction due to a current deviation is increasing. As an absolute value of an position shift amount to the source side (the left side) ΔX is increasing, the degree of a current increase due to a current deviation is increasing. These absolute values of current deviation amounts are symmetrical each other relative to the position shift amount ΔX=0 μm.

As illustrated in FIGS. 21C and 22B, as an area of the overlap region 116 where the channel protective film 115 overlaps the source electrode 118 relatively becomes smaller, that is, as an area of the overlap region 117 where the channel protective film 115 overlaps the drain electrode 119 relatively becomes larger, the channel current Ic that flows from the drain electrode 119 to the source electrode 118 becomes slightly larger nonlinearly along a downward convex curve.

Patent Literature 1: Unexamined Japanese Patent Application KOKAI Publication No. 2001-195012

### SUMMARY

It is preferable to reduce a current deviation amount to a maximum extent that is caused by a position shift of the source and drain electrodes 118, 119 from their desired positions due to a manufacturing process of each of the components of the aforementioned TFT.

The present invention has been made in light of the aforementioned problems and has an objective to provide a pixel circuit substrate, a display device and an electronic equipment that have a structure to obtain a stable display characteristic, as well as a method for manufacturing the pixel circuit substrate.

In order to achieve the aforementioned objective, a pixel circuit substrate according to the present invention includes:

a pixel electrode;

a first drive element connected to one side of the pixel electrode; and

a second drive element that is connected to the first drive element in parallel and is connected to the other side opposite to the one side of the pixel electrode.

Each of the first drive element and second drive element may be a drive transistor having a gate electrode, a semiconductor layer, a source electrode and a drain electrode.

The source and drain electrodes of the first drive element and the source and drain electrodes of the second drive element may have a mirror symmetry structure relative to the pixel electrode.

One of the source electrode of the first drive element and the drain electrode of the first drive element may be connected to the one side of the pixel electrode, and one of the source electrode of the second drive element and the drain electrode of the second drive element may be connected to the other side of the pixel electrode.

The other of the source electrode of the first drive element and the drain electrode of the first drive element may be connected to an anode line, and the other of the source electrode of the second drive element and the drain electrode of the second drive element may be connected to the anode line.

Each of the first drive element and second drive element may further include a channel protective film disposed between the semiconductor layer and the source and drain electrodes.

The one side and the other side of the pixel electrode may be parallel to each other.

The pixel circuit substrate according to the present invention may further include a switching element to switch between the first drive element and the second drive element.

The switching element may be a transistor having a gate electrode connected to a gate line.

The switching element is disposed on the other side of the pixel electrode, and the first drive element is disposed on the one side of the pixel electrode, facing the switching element, not the second drive element.

The pixel circuit substrate according to the present invention further includes a switching element that has a gate electrode and source and drain electrodes and switches between the first drive element and the second drive element, in which one of the source and drain electrodes of switching element may be connected to a data line and the other of the source and drain electrodes may be connected to the gate electrode of the first drive element and the gate electrode of the second drive element.

The pixel circuit substrate according to the present invention further includes a first switching element and a second switching element, each having a gate electrode and source and drain electrodes, in which one of the source and drain electrodes of the first switching element may be connected to the gate electrode of the first drive element and the gate electrode of the second drive element and, one of the source and drain electrodes of the second switching element may be connected to the source electrode of the first drive element and the source electrode of the second drive element, or may be connected to the drain electrode of the first drive element and the drain electrode of the second drive element.

A display device includes the pixel circuit substrate, a counter electrode, and a luminescent layer disposed between the pixel electrode and the counter electrode.

An electronic equipment includes the display device.

A method for manufacturing a pixel circuit substrate, comprising:

forming a pixel electrode; and

forming a first drive element connected to one side of the pixel electrode and a second drive element that is connected to the first drive element in parallel and is connected to the other side opposite to the one side of the pixel electrode.

Each of the first drive element and second drive element may be a drive transistor having a gate electrode, a semiconductor layer and source and drain electrodes.

The semiconductor layer of the first drive element and the semiconductor layer of the second drive element may be formed by patterning with the use of a first resist mask; and

the source and drain electrodes of the first drive element and the source and drain electrodes of the second drive element may be formed by patterning with the use of a second resist mask that is different from the first resist mask.

Each of the first drive element and second drive element may have a channel protective film disposed between the semiconductor layer and the source and drain electrodes.

The channel protective film of the first drive element and the channel protective film of the second drive element may be formed with the use of a third resist mask that is different from the first and second resist masks.

The present invention can realize a stable display characteristics.

### BRIEF DESCRIPTION OF THE DRAWINGS

A more complete understanding of this application can be obtained when the following detailed description is considered in conjunction with the following drawings, in which:

FIG. 1 is plain view illustrating a configuration of a display device according to an embodiment of the present invention;

FIG. 2A is an equivalent circuit schematic illustrating a pixel drive circuit of a luminescent pixel according to a first embodiment;

FIG. 2B is an equivalent circuit schematic illustrating a pixel drive circuit of a luminescent pixel according to a reference example;

FIG. 3 is a plain view of the luminescent pixel according to the first embodiment;

FIG. 4A is a cross sectional view taken on line IVa-IVa of FIG. 3;

FIG. 4B is a cross sectional view taken on line IVb-IVb of FIG. 3;

FIG. 5A is a diagram that corresponds to the cross sectional view taken on line IVa-IVa of FIG. 3 and illustrates a method for manufacturing a display device according to the first embodiment;

FIG. 5B is a diagram that corresponds to the cross sectional view taken on line IVa-IVa of FIG. 3 and illustrates a method for manufacturing a display device according to the first embodiment;

FIG. 6A is a diagram illustrating a method for manufacturing a display device subsequent to FIG. 5 according to the first embodiment;

FIG. 6B is a diagram illustrating a method for manufacturing a display device subsequent to FIG. 5 according to the first embodiment;

FIG. 7A is a schematic view illustrating a pixel drive circuit in which positions of source and drain electrodes are not shifted in the left and right direction;

FIG. 7B is a graph illustrating a relationship between a position shift amount ΔX and a channel current;

FIG. 8A is a schematic view illustrating a pixel drive circuit in which positions of source and drain electrodes are shifted in the left and right direction to the upper right direction;

FIG. 8B is a graph illustrating a relationship between a position shift amount ΔX and a channel current;

FIG. 9A is a schematic view illustrating a pixel drive circuit in which positions of source and drain electrodes are shifted in the left and right direction to the lower left direction;

FIG. 9B is a graph illustrating a relationship between a position shift amount ΔX and a channel current;

FIG. 10A is a table illustrating a relationship between a position shift amount of source and drain electrodes in a X-axis direction and channel currents Ic of a reference example and an embodiment;

FIG. 10B is a table illustrating a relationship between a position shift amount of source and drain electrodes in a X-axis direction and standardized values of channel currents Ic of a reference example and an embodiment;

FIG. 11A is an equivalent circuit schematic illustrating a pixel drive circuit of a luminescent pixel according to a second embodiment;

FIG. 11B is an equivalent circuit schematic illustrating a pixel drive circuit of a luminescent pixel according to a reference example;

FIG. 12 is a plain view of the luminescent pixel according to the second embodiment;

FIG. 13A is a cross sectional view taken on line XIIIa-XIIIa of FIG. 12;

FIG. 13B is a cross sectional view taken on line XIIIb-XIIIb of FIG. 12;

FIG. 14 is an entire configuration of a display device illustrating operation of a pixel drive circuit according to the second embodiment of the present invention;

FIG. 15A is a diagram that corresponds to the cross sectional view taken on line XIIIa-XIIIa of FIG. 12 and illustrates a method for manufacturing a display device according to the second embodiment;

FIG. 15B is a diagram that corresponds to the cross sectional view taken on line XIIIa-XIIIa of FIG. 12 and illustrates a method for manufacturing a display device according to the second embodiment;

FIG. 16A is a diagram illustrating a method for manufacturing a display device subsequent to FIG. 15 according to the second embodiment;

FIG. 16B is a diagram illustrating a method for manufacturing a display device subsequent to FIG. 15 according to the second embodiment;

FIG. 17A is a front perspective view of a digital camera seen from oblique front position as an electronic equipment for which a display device according to an embodiment of the present invention is used;

FIG. 17B is a rear perspective view of the same digital camera seen from oblique rear position;

FIG. 18 is a perspective view illustrating a personal computer as an electronic equipment for which a display device according to an embodiment of the present invention is used;

FIG. 19 is a view illustrating a cellular phone as an electronic equipment for which a display device according to an embodiment of the present invention is used;

FIG. 20 is a view illustrating a television device as an electronic equipment for which a display device according to an embodiment of the present invention is used;

FIG. 21A is a cross sectional view of an inversely-staggered and channel protective film type TFT;

FIG. 21B is a plain view of an inversely-staggered and channel protective film type TFT;

FIG. 21C is a schematic view illustrating a position relationship between source and drain electrodes and a gate electrode (a channel protective film) in an inversely-staggered and channel protective film type TFT;

FIG. 22A is a graph illustrating a relationship between a gate voltage Vg and a channel current Ic according to a position relationship between the source and drain electrodes and the gate electrode of the TFT illustrated in FIGS. 21; and

FIG. 22B is a graph illustrating a relationship between a position shift amount of source and drain electrodes and a current deviation from a current I that flows between the source electrode and the drain electrode.

### DETAILED DESCRIPTION

A pixel circuit substrate, a display device and a method for manufacturing a display device including the pixel circuit substrate according to an embodiment of the present invention will be described with reference to drawings. The following embodiments will be described with respect to an active drive type display device using a bottom emission type organic electro luminescence (EL) element, as an example.

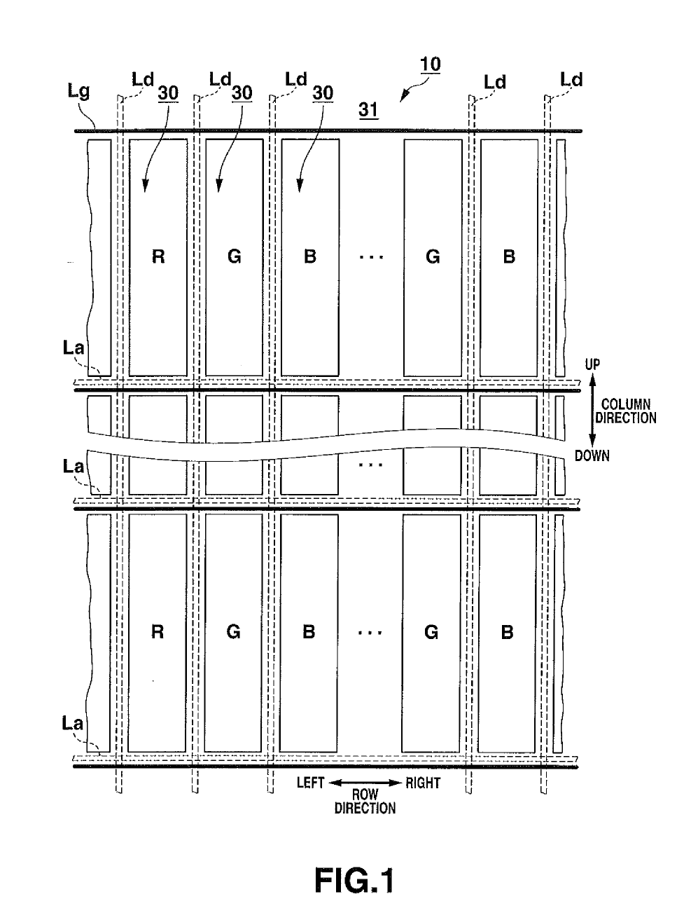

(First Embodiment) As illustrated in FIG. 1, in a display device having a pixel circuit substrate according to a first embodiment, three luminescent pixels 30, each emitting red (R), green (G), or blue (B), are set to be one set, and a plurality of these sets are repeatedly arranged in a row direction (a left and right direction) on a substrate 31 such as glass and a plurality of same color luminescent pixels 30 are arranged in a column direction (an up and down direction). In this way, the luminescent pixels 30, each emitting each of RGB, are arranged in a matrix manner. Each of the luminescent pixels 30 includes a luminescent element 21 that is an organic EL element as a display element emitting each of RGB.

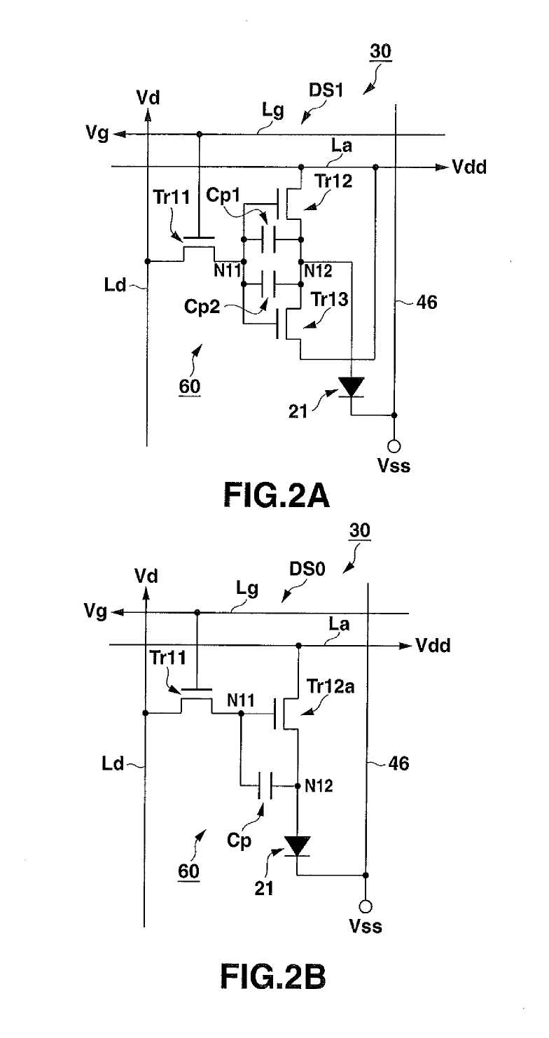

As illustrated in FIG. 2A, each of the luminescent pixel 30 includes the luminescent element 21 and a pixel drive circuit DS1 that activates the luminescent element 21. The pixel circuit substrate has the substrate 31, the pixel drive circuit DS1, and a pixel electrode 42 of the luminescent element 21.

The pixel drive circuit DS1 includes a selection transistor Tr11, a first drive transistor Tr12, a second drive transistor Tr13 and capacitors Cp1, Cp2. All of the selection transistor Tr11 and first and second drive transistors Tr12, Tr13 are inversely-staggered, N-channel type thin film transistors (TFTs) including a semiconductor layer containing amorphous silicon or microcrystal silicon. The capacitors Cp1, Cp2 store, as an electric charge, data for display such as a gradation signal supplied from a data line Ld, which will be described later.

The pixel drive circuit DS1 according to the present embodiment includes two drive transistors, that is, the first and second drive transistors Tr12, Tr13, as illustrated in FIG. 2A. In contrast, a pixel drive circuit DS0 in a reference example illustrated in FIG. 2B is different from the pixel drive circuit DS1 in the present embodiment in that the pixel drive circuit DS0 has only one drive transistor Tr12a. For comparison, description will be made, on the premise that a channel width of the drive transistor Tr12a of the reference example is equal to the sum of respective channel widths of the first and second drive transistors Tr12, Tr13 of the present embodiment.

As illustrated in FIGS. 1 and 2A, an anode line La connected to each of a plurality of pixel drive circuits DS1 arranged in a row direction, a plurality of data lines Ld connected to each of a plurality of pixel drive circuits DS1 arranged in a column direction, and a gate line Lg to select (switch) each of the selection transistors Tr11 of the plurality of pixel drive circuits DS1 arranged in a row direction are formed on the substrate 31.

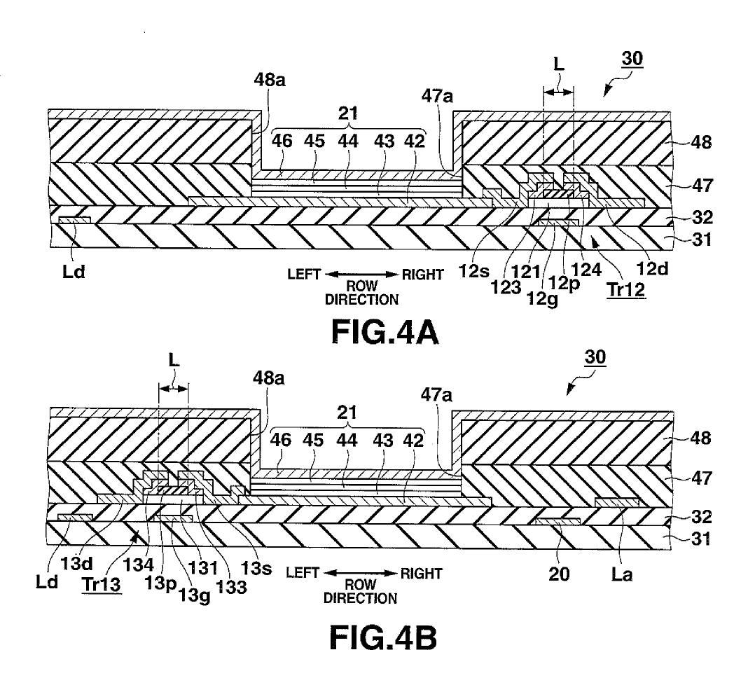

In the pixel drive circuit DS1 according to the present embodiment illustrated in FIG. 2A, in the selection transistor Tr11, a gate electrode is connected to the gate line Lg, a drain electrode is connected to the data line Ld, and a source electrode is connected to a node N11. In the first and second drive transistors Tr12, Tr13, a gate electrode is connected to the node N11, a drain electrode is connected to the anode line La, and a source electrode is connected to a node N12, respectively. In the capacitor Cp1, both ends thereof are connected respectively to a gate electrode and a source electrode (node N11, N12) of the first drive transistor Tr12. In the capacitor Cp2, both ends thereof are connected respectively to a gate electrode and a source electrode (node N11, N12) of the second drive transistor Tr13. The capacitors Cp1, Cp2 are set to have the same capacity. Each of these capacitors Cp1, Cp2 is a capacity component that has an auxiliary capacity additionally provided between the gate and source of the first and second drive transistors Tr12, Tr13 or that has a parasitic capacity and an auxiliary capacity between the gate and source of the first and second drive transistors Tr12, Tr13. The node N12 is connected to an anode of the luminescent element 21, a cathode of the luminescent element 21 is connected to a counter electrode 46. In this way, the first and second drive transistors Tr12, Tr13 are connected in parallel between the anode line La and node N12 (luminescent element 21) and seemingly function as one transistor. A reference voltage Vss is applied to the cathode (the counter electrode 46, see FIG. 4) of the luminescent element 21.

Meanwhile, in the pixel drive circuit DS0 of the reference example illustrated in FIG. 2B, in the selection transistor Tr11, a gate electrode is connected to the gate line Lg, a drain electrode is connected to the data line Ld, and a source electrode is connected to the node N11, respectively. In the drive transistor Tr12a, a gate electrode is connected to the node N11, a drain electrode is connected to the anode line La, and a source electrode is connected to the node N12, respectively. The capacitor Cp is connected between the gate electrode and source electrode (node N11, N12) of the drive transistor Tr12a. The node N12 is connected to an anode of the luminescent element 21, and a cathode of the luminescent element 21 is connected to the counter electrode 46. In this way, the drive transistor Tr12a is connected between the anode line La and node N12.

Referring to FIGS. 1 and 2A, the gate line Lg is connected to a gate driver disposed on a periphery of a luminescent panel. A selection voltage signal (a scan signal) is applied to the gate line Lg from the gate driver in order to set the plurality of luminescent pixels 30 connected to the gate line Lg and arranged in a row direction into a selected state at a predetermined timing.

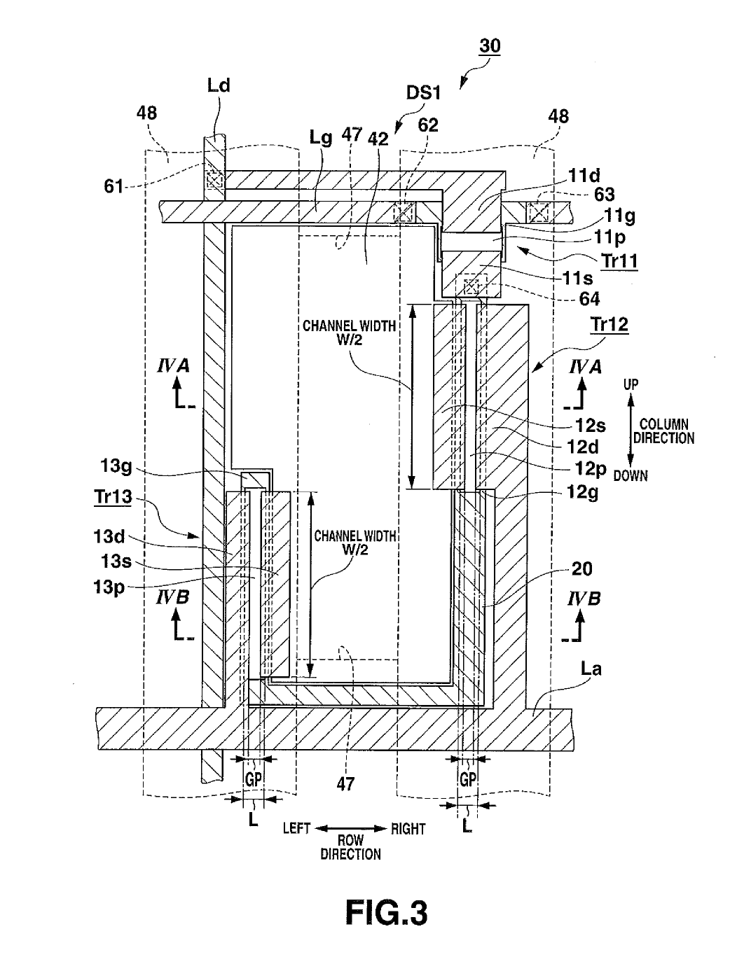

The data line Ld is connected to a data driver arranged on a periphery of the luminescent panel, and a data voltage (a gradation signal) according to luminescent data is applied from the data driver to the data line Ld at a timing in synchronization with the selected state of the luminescent pixels 30. The anode line La (a current supply line) is connected directly or indirectly to a predetermined high potential power source. This sets a state in which a drive current according to luminescent data flows from the anode line La through the plurality sets of first and second drive transistors Tr12, Tr13 arranged in a row direction to the approximately rectangular pixel electrode 42 (see FIG. 3) of the luminescent element 21. That is, a predetermined supply voltage Vdd (>reference voltage Vss), which has a sufficiently higher potential than that of the reference voltage Vss applied to the counter electrode 46 of the luminescent element 21, is applied to the anode line La.

Referring to FIGS. 3, 4A, 4B, on the substrate 31 of each of the luminescent pixels 30, formed are the selection transistor Tr11 to select the luminescent element 21, and the gate electrodes 12g, 13g of the first and second drive transistors Tr12, Tr13 to supply a drive current to the luminescent element 21. On the substrate 31 adjacent to each of the luminescent pixels 30, the data line Ld is formed extending along a column direction (an up and down direction). On the substrate 31, an insulating film 32 is formed to cover the data line Ld and gate electrodes 11g, 12g , 13g. On the substrate 31, a conductive layer 20 is formed to connect the gate electrodes 12g, 13g to each other.

Referring to FIGS. 3, 4A, 4B, the source electrodes 12s, 13s of the first and second drive transistors Tr12, Tr13 are connected to the pixel electrode 42 on the insulating film 32, the drain electrodes 12d, 13d are connected to the anode line La on the substrate 31. Specifically, the source electrode 12s of the first drive transistor Tr12 is connected to one side (right side) of the rectangular pixel electrode 42 (organic EL element 21), and the source electrode 13s of the second drive transistor Tr13 is connected to the other side (left side) opposite to the one side of the pixel electrode 42. The one side and the other side of this pixel electrode 42 are parallel to each other. The gate electrodes 12g, 13g are connected to each other through the conductive layer 20 on the substrate 31. The source electrode 12s and drain electrode 12d of the first drive transistor Tr12 are disposed at the left and right sides of a channel protective film 12p, respectively, in each of the FIGS. 3, 4A. The source electrode 13s and drain electrode 13d of the second drive transistor Tr13 are disposed at the right and left sides of a channel protective film 13p, respectively, in each of the FIGS. 3, 4B. Under the source and drain electrodes 12s, 12d of the first drive transistor Tr12, ohmic contact layers 123, 124, which include amorphous silicon containing n-type impurities, are formed, respectively. Under the source and drain electrodes 13s, 13d of the second drive transistor Tr13, ohmic contact layers 133, 134, which include amorphous silicon containing n-type impurities, are formed, respectively. The channel protective film 12p that is a protective insulating film is disposed on a semiconductor layer 121 containing amorphous silicon or microcrystal silicon between the source and drain electrodes 12s, 12d and between the ohmic contact layers 123, 124. The channel protective film 13p is disposed on a semiconductor layer 131 containing amorphous silicon or microcrystal silicon between the source and drain electrodes 13s, 13d and between the ohmic contact layers 133, 134. The semiconductor layers 121, 131 are formed on the insulating film 32 that functions as a gate insulating film. The ohmic contact layers 123, 124 are disposed for a low resistance connection to the source and drain electrodes 12s, 12d and the semiconductor layer 121, respectively. The ohmic contact layers 133, 134 are disposed for a low resistance connection to the source and drain electrodes 13s, 13d and the semiconductor layer 131, respectively.

The anode line La and gate line Lg are formed using a source/drain conductive layer that is for forming the source electrodes 11s, 12s, 13s and drain electrodes 11d, 12d, 13d of the respective transistors Tr11, Tr12, Tr13. The data line Ld and conductive layer 20 are formed using a gate conductive layer that is for forming the gate electrodes 11g, 12g, 13g of the respective transistors Tr11, Tr12, Tr13. On the insulating film 32 between the data line Ld and drain electrode 11d, a contact portion (contact hole) 61 is formed to connect the data line Ld and drain electrode 11d. On the insulating film 32 between the gate line Lg and the both ends of the gate electrode 11g, contact portions (contact holes) 62, 63 are formed to connect the gate line Lg and gate electrode 11g. On the insulating film 32 between the source electrode 11s and gate electrode 12g, a contact portion (contact hole) 64 is formed to connect the source electrode 11s and gate electrode 12g. These contact portions 61 to 64 properly connect, in a direction of thickness of the substrate, a lower connecting portion made by patterning of a gate conductive layer, which becomes the gate electrodes 11g, 12g, 13g of the selection transistor Tr11, first and second drive transistors Tr12, Tr13, the data line Ld, and the conductive layer 20, with an upper connecting portion made by patterning the source/drain conductive layer, which becomes the source electrodes 11s, 12s, 13s and drain electrodes 11d, 12d, 13d of the selection transistor Tr11, first and second drive transistors Tr12, Tr13, the anode line La, and the gate line Lg.

The drive transistor Tr12a in the reference example illustrated in FIG. 2B has a channel width of W(μm) whereas each of the first and second drive transistors Tr12, Tr13 in the present embodiment illustrated in FIG. 2A has a channel width of W/2(μm). In this way, the sum of the channel widths of the first and second drive transistors Tr12, Tr13 is equal to the channel width W of the drive transistor Tr12a in the reference example (W=W/2+W/2). Channel lengths L of the semiconductor layers 121, 131 of the first and second drive transistors Tr12, Tr13 are equal to each other, and a distance Gp between the source electrode 12s and drain electrode 12d of the first drive transistor Tr12 and a distance Gp between the source electrode 13s and drain electrode 13d of the second drive transistor Tr13 are equal to each other. As described above, the first and second drive transistors Tr12, Tr13, as with the drive transistor Tr12a, are connected between the anode line La and node N12. Therefore, the first and second drive transistors Tr12, Tr13 function as a TFT having a channel width of W(μm), as with the drive transistor Tr12a in the reference example.

As illustrated in FIGS. 4A and 4B, the luminescent element 21 includes the pixel electrode 42 as an anode electrode, a hole injection layer 43, an interlayer 44, a luminescent layer 45, and a counter electrode 46 as a cathode electrode. The hole injection layer 43 includes at least one of an organic high-molecular material or an organic low-molecular material that can be subjected to hole (positive hole) injection and transportation, and an inorganic oxide, and the hole injection layer 43 has a function of supplying a hole to the luminescent layer 45 under a predetermined electric field. The interlayer 44 has a function of suppressing a hole injection property of the hole injection layer 43 thereby to facilitate recombination of an electron and a hole in the luminescent layer 45, as a result, increasing a luminous efficiency of the luminescent layer 45. The luminescent layer 45 includes an organic high-molecular material or an organic low-molecular material that has a function of emitting light by recombination of a hole from the pixel electrode 42 and an electron from the counter electrode 46.

These hole injection layer 43, interlayer 44 and luminescent layer 45 become a carrier transportation layer that transports an electron and hole as a carrier under a predetermined electric field. An interlayer insulating film 47 is a protective film that covers the tops of transistors Tr11, Tr12, Tr13, data line Ld, gate line Lg, and anode line La, as well as a periphery of the pixel electrode 42, and in the interlayer insulating film 47 an approximately rectangular opening 47a is formed so as to define a luminescent region of the luminescent pixel 30. On the interlayer insulating film 47, a stripe-shaped dividing wall 48 is formed extending in a column direction (up and down direction in FIG. 3). The dividing wall 48 has stripe-shaped openings 48a corresponding to a plurality of openings 47a along a column direction.

The counter electrode 46 is an electrode layer that is continuous and faces the pixel electrode 42 of all of the luminescent pixels 30 (luminescent element 21) arranged in a matrix manner on the substrate 31. The counter electrode 46 functions as a common electrode to which a predetermined low voltage (a reference voltage Vss (a reference potential) such as a ground potential GND) is commonly applied.

The first drive transistor Tr12 includes the semiconductor layer 121, channel protective film 12p, drain electrode 12d, source electrode 12s, ohmic contact layers 123, 124, gate electrode 12g, and insulating film 32 between the semiconductor layer 121 and gate electrode 12g.

The second drive transistor Tr13 includes the semiconductor layer 131, channel protective film 13p, drain electrode 13d, source electrode 13s, ohmic contact layers 133, 134, gate electrode 13g, and insulating film 32 between the semiconductor layer 131 and gate electrode 13g. The selection transistor Tr11 includes the semiconductor layer (not illustrated), channel protective film 11p, drain electrode 11d, source electrode 11s, ohmic contact layer (not illustrated), gate electrode 11g, and insulating film 32 between the semiconductor layer and gate electrode 11g.

In each of the transistors Tr11, Tr12, Tr13, the gate electrodes 11g, 12g, 13g is formed of an opaque gate conductive layer containing at least one of an Mo film, a Cr film, an Al film, a Cr/Al laminated film, an AlTi alloy film or AlNdTi alloy film, and an MoNb alloy film. The drain electrodes 11d, 12d, 13d and source electrodes 11s, 12s, 13s is formed of a source/drain conductive layer containing at least one of aluminum/titanium (AlTi)/Cr, AlNdTi/Cr, and Cr.

The pixel electrode 42 is made of a transparent conductive material such as Indium Tin Oxide (ITO) and ZnO. The each pixel electrode 42 is insulated from other pixel electrode 42 on its adjacent luminescent pixel 30 by being spaced apart from the other pixel electrode 42.

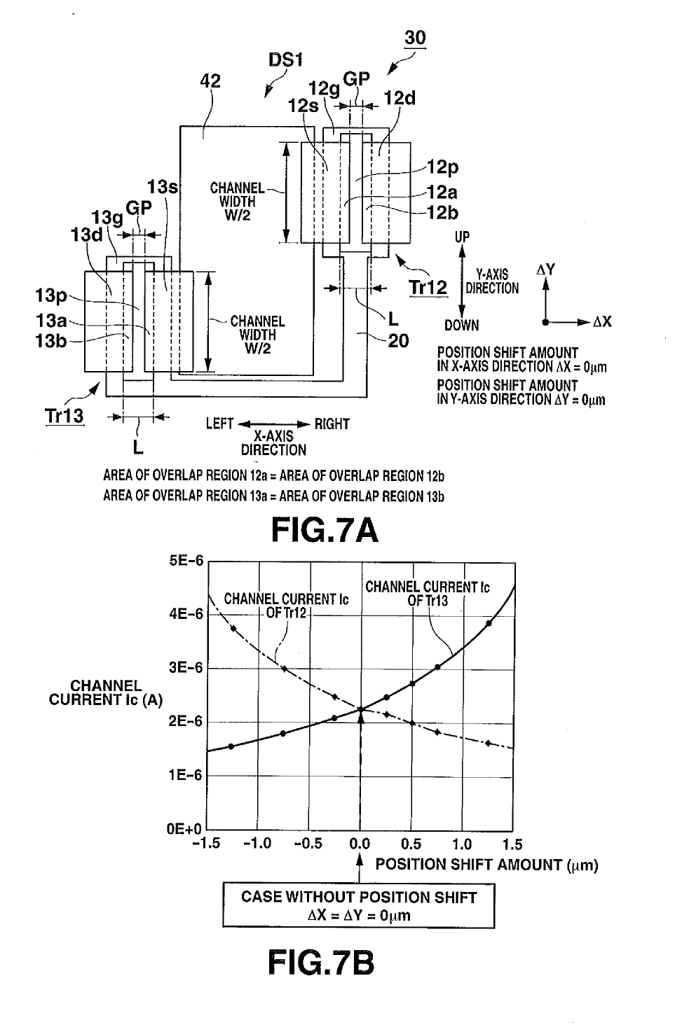

According to the present embodiment, in the first drive transistor Tr12, an area of an overlap region 12a of the source electrode 12s and the channel protective film 12p and an area of an overlap regions 12b of the drain electrode 12d and the channel protective film 12p are set to be equal to each other (see FIG. 7A). In the second drive transistor Tr13, an area of an overlap region 13a of the source electrode 13s and the channel protective film 13p and an area of an overlap region 13b of the drain electrode 13d and the channel protective film 13p are set to be equal to each other (see FIG. 7A).

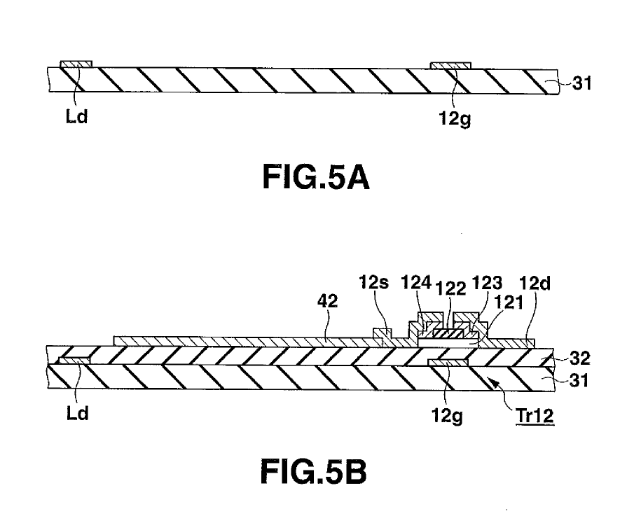

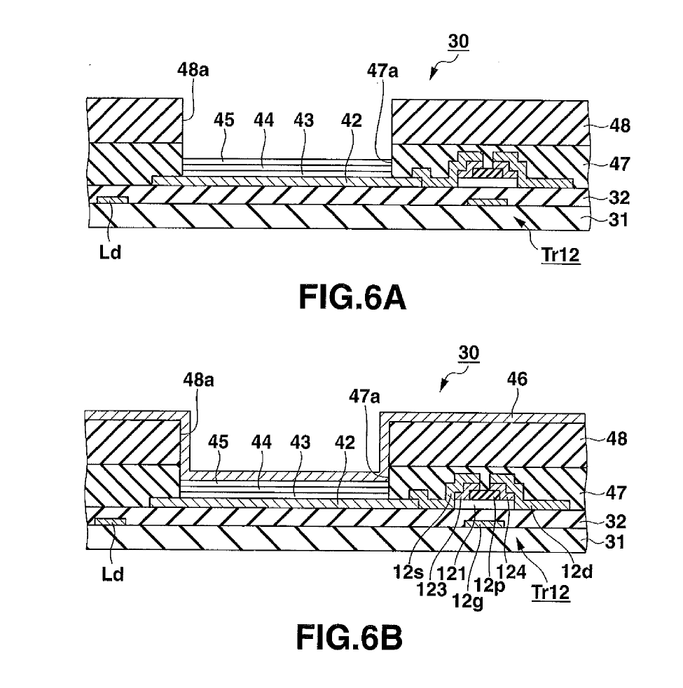

Next, a method for manufacturing a display device according to the present embodiment will be described with reference to FIGS. 5 and 6. In this embodiment, the selection transistor Tr11 and second drive transistor Tr13 are formed in the same process as that of the first drive transistor Tr12. Therefore, part of a method for forming the selection transistor Tr11 and second drive transistor Tr13 will not be described since it has been described regarding a method for forming the first drive transistor Tr12.

First, as illustrated in FIG. 5A, on a substrate 31 such as glass as a luminescent pixel substrate, a gate conductive film that contains at least one of an Mo film, a Cr film, an Al film, a Cr/Al laminated film, an AlTi alloy film or AlNdTi alloy film, and an MoNb alloy film, for example, is formed by a sputtering method or a vacuum deposition method; this conductive film is subjected to patterning to form the gate electrode 12g of the first drive transistor Tr12 and data line Ld with the use of a resist mask by photolithography, as well as to patterning in the gate electrodes 11g, 13g of the selection transistor Tr11, second drive transistor Tr13 and the conductive layer 20, which is not illustrated in FIG. 5A.

Next, as illustrated in FIG. 5B, on the gate electrode 12g and data line Ld, the insulating film 32 having a insulating material such as a silicon dioxide film and a silicon nitride film is formed by, for example, a chemical vapor deposition (CVD) method. Next, on the insulating film 32, an amorphous silicon layer that becomes a semiconductor layer, and an insulating layer, such as a silicon dioxide film and a silicon nitride film, that becomes a channel protective film, are continuously laminated by, e.g. a CVD method. This insulating layer is subjected to patterning with the use of a resist mask by photolithography to form the channel protective film 12p, as well as the channel protective films 11p, 13p of the selection transistor Tr11 and second drive transistor Tr13. Next, an amorphous silicon layer containing n-type impurities is deposited onto the channel protective film, which is subjected to etching with the use of a resist mask by photolithography to pattern an outer circumference of each of the ohmic contact layers 123, 124, 133, 134 of the transistors Tr11, Tr12, Tr13. Then, a lower amorphous silicon layer is subjected to etching to pattern the semiconductor layers 121, 131 of the transistors Tr11, Tr12, Tr13. At this time, a channel length L of each of the semiconductor layers 121, 131 of the transistors Tr11, Tr12, Tr13 is defined by a length in a row direction (X-axis direction) of each of the channel protective films 11p, 12p, 13p of the transistors Tr11, Tr12, Tr13, and is always fixed regardless of a position shift of the source or drain electrodes.

Next, on the insulating film 32, a transparent conductive film such as ITO is formed by, e.g. a spattering method or a vacuum deposition method, and is subjected to patterning with the use of a resist mask by photolithography to form the pixel electrode 42.

Then, the contact holes, which will become the contact portions 61 to 64, are formed in the insulating film 32, after that, a source/drain conductive film containing at least one of an Mo film, a CR film, an Al film, a Cr/Al laminated film, an AlTi alloy film or AlNdTi alloy film and an MoNb alloy film is formed by, e.g. a sputtering method or vacuum deposition method, and is embedded into the contact portions 61 to 64. After that, the source/drain conductive film is subjected to patterning with the use of a resist mask by photolithography to form the selection transistor Tr11, the source and drain electrodes 12s, 12d, 13s, 13d of the first drive transistor Tr12 and second drive transistor Tr13, the anode line La, the gate line Lg (see FIG. 4B), and also the ohmic contact layers under and between the source and drain electrodes of the transistors Tr11, Tr12, Tr13 are subjected to etching to form the ohmic contact layers 123, 124, 133, 134 of the transistors Tr11, Tr12, Tr13. In this way, each of the gate conductive film, channel protective film, and source/drain conductive film is patterned independently with the use of a resist mask by photolithography, a relative position shift of the source and drain electrodes may occur. Since the source and drain electrodes 12s, 12d, 13s, 13d of the selection transistor Tr11, first drive transistor Tr12 and second drive transistor Tr13 are formed by the same photolithography process, their degree of the position shift is the same. Therefore, a distance between the source electrode 11s and drain electrode 12d of the selection transistor Tr11, a distance Gp between the source electrode 12s and drain electrode 12d of the first drive transistor Tr12, and a distance Gp between the source electrode 13s and drain electrode 13d of the second drive transistor Tr13 are always fixed even if a position shift occurs. The degree of the relative position shift of each of the source and drain electrodes 12s, 12d, 13s, 13d of the selection transistor Tr11, first drive transistor Tr12 and second drive transistor Tr13 is equal to the degree of the relative position shift of each of their corresponding gate electrodes 11g, 12g, 13g, and is equal to the degree of the relative position shift of each of their corresponding channel protective films 11p, 12p, 13p. The source electrode 12s of the first drive transistor Tr12 and the source electrode 13s of the second drive transistor Tr13 are formed so as to connect to the right side and the left side, respectively, two sides of the pixel electrode 42 that is along a column direction and orthogonal to a row direction (see FIG. 4B).

Next, as illustrated in FIG. 6A, the interlayer insulating film 47 having a silicon nitride film is formed by, e.g. the CVD method, so as to cover the tops of the transistor Tr11, transistor Tr12, transistor Tr13, and data line Ld. After that, in the interlayer insulating film 47 the opening 47a is formed with the use of a resist mask by photolithography. Next, photoactive polyimide is coated to cover the interlayer insulating film 47, which is subjected to exposure and development with the use of a mask to pattern the dividing wall 48 having the opening 48a.

After that, as illustrated in FIG. 6B, by using a nozzle printing device that continuously flows a liquid or an inkjet device that ejects a plurality of separate liquid droplets, an organic-compound-containing liquid that contains a hole injection material is selectively applied onto the pixel electrode 42 surrounded by the opening 47a. Then, the substrate 31 is heated under an air atmosphere to volatilize a solvent of the organic-compound-containing liquid that contains an organic high-molecular hole injection and transportation material, thereby forming the hole injection layer 43.

As this organic-compound-containing liquid, for example, a PEDOT/PSS aqueous solution that is a dispersion liquid in which polyethylenedioxy thiophene (PEDOT) as a conductive polymer and polystyrene sulfonate (PSS) as a dopant are dispersed in a water solvent is used.

Next, by using a nozzle printing device or an inkjet device, an organic-compound-containing liquid that contains a material to become the interlayer 44 is applied onto the hole injection layer 43, and then is subjected to drying by heating in a nitrogen atmosphere or drying by heating in vacuum, thereby removing a residual solvent to form the interlayer 44.

Next, the interlayer 44 is coated with an organic-compound-containing liquid in which a luminescent polymer material (R, G, B) such as a conjugated double bond polymer, e.g. polyparaphenylene vinylene series and polyfluorene series is solved in an organic solvent such as tetralin, tetramethylbenzene, mesitylene, and xylene, by using a nozzle printing device or an inkjet device; and is subjected to heating in a nitrogen atmosphere, thereby removing a residual organic solvent to form the luminescent layer 45.

After that, as illustrated in FIG. 6B, on the substrate 31 on which the luminescent layer 45 has been formed, the counter electrode 46, which has a two-layer structure composed of a layer having a material with a low work function such as Li, Mg, Ca, Ba and a light reflective conductive layer such as Al, is formed by using vacuum deposition or sputtering.

Next, a working effect of a display device according to the present embodiment will be described with reference to FIGS. 7 to 10. In FIGS. 7 to 10, an n-channel type TFT is used. A horizontal axis in FIGS. 7B, 8B, 9B has a positive value if the source and drain electrodes shift rightward relative to a reference position, which will be described later; and it has a negative value if the source and drain electrodes shift leftward, where W (a channel width)=700 μm, L (a channel length)=7.4 μm, a gate voltage Vg=5V, and a data voltage Vd=10V.

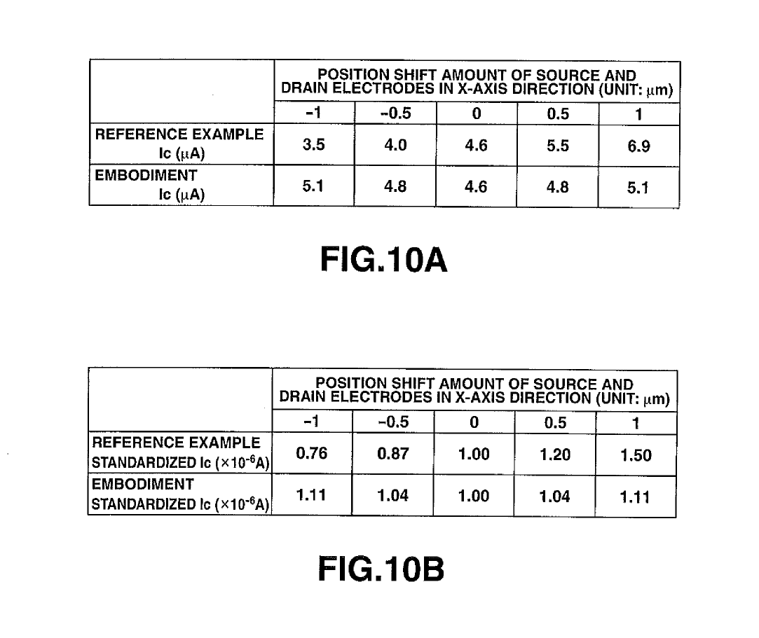

First, as illustrated in FIG. 7A, in the luminescent pixel 30, if there is no position shift of the source and drain electrodes 12s, 12d, 13s, 13d in a left and right direction relative to the channel protective films 12p, 13p (a position shift amount in an X axis direction ΔX=a position shift amount in a Y axis direction ΔY=0 μm) (hereinafter positions of the source and drain electrodes 12s, 12d, 13s, 13d illustrated in FIG. 7A will be referred to as “the reference position”), in the pixel drive circuit DS1, a channel current Ic that flows through the first drive transistor Tr12 is equal to a channel current Ic that flows through the second drive transistor Tr13 (see FIGS. 10A and 10B) as illustrated in FIG. 7B. In this case, when the sum of the channel currents Ic is set to be a reference current value, a current deviation amount from the reference current value is 0 (%). By this, in a display device having a plurality of luminescent pixels 30 including the luminescent element 21 as a display element, each of the luminescent pixels 30 can emit a uniform light. In this case, the sum of both of the channel currents Ic is 4.6×10⁻⁶ A, as illustrated in FIG. 10A.

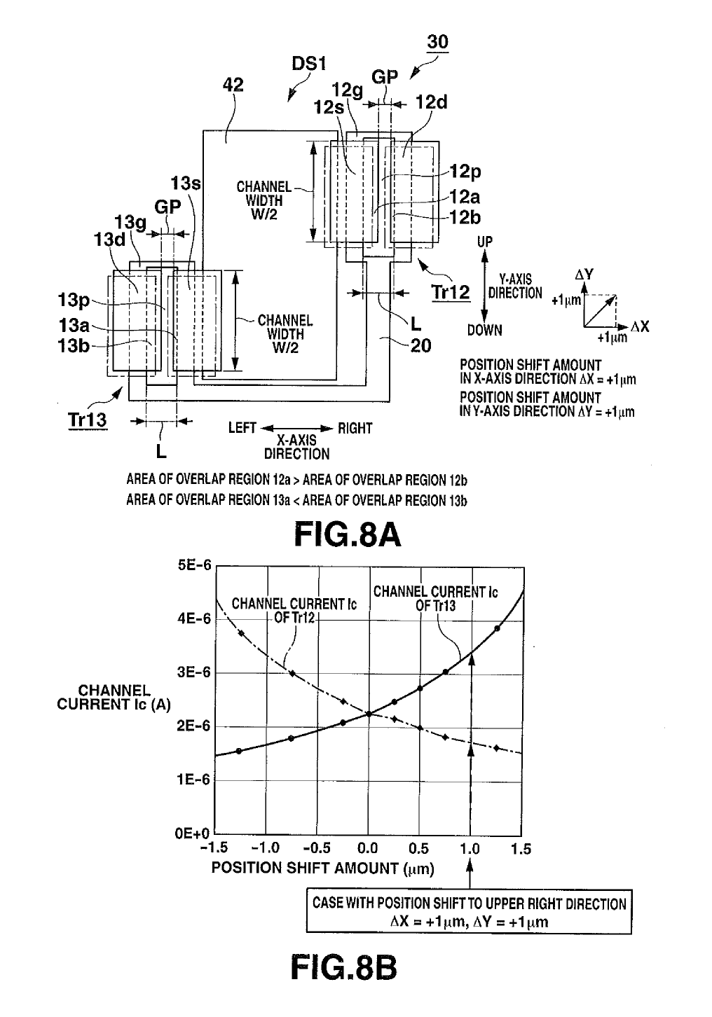

As illustrated in FIG. 8A, in the luminescent pixel 30, if the source and drain electrodes 12s, 12d, 13s, 13d shift to the upper right direction relative to the channel protective film 12p, 13p, from the reference position illustrated in FIG. 7A (a position shift amount in an X axis direction ΔX=a position shift amount in a Y axis direction ΔY=+1 μm), a channel current Ic that flows through the second drive transistor Tr13 is larger than that of a case where the second drive transistor Tr13 is at the reference position as illustrated in FIG. 8B. However, since a channel current Ic that flows through the first drive transistor Tr12 is smaller than that of a case where the first drive transistor Tr12 is at the reference position, a change of the channel current Ic is offset. Therefore, the sum of both of the channel currents Ic becomes about 5.1×10⁻⁶ A (see FIGS. 10A and 10B), and is approximately equal to the case illustrated in FIGS. 7A, 7B. It is because the source electrode 12s of the first drive transistor Tr12 and the source electrode 13s of the second drive transistor Tr13 that are connected to the pixel electrode 42 are located on the right and left, respectively, relative to the pixel electrode 42. That is, a set of the source and drain electrodes 12s, 12d of the first drive transistor Tr12 and a set of the source and drain electrodes 13s, 13d of the second drive transistor Tr13 are minor symmetrical to each other relative to the pixel electrode 42.

Such a structure shifts the source and drain electrodes 12s, 12d of the first drive transistor Tr12 rightward relative to the channel protective film 12p, thereby increasing an area of the overlap region 12a, as well as reducing an area of the overlap region 12b, in comparison with the case where the source and drain electrodes 12s, 12d are at the reference position. Therefore, a channel current Ic of the first drive transistor Tr12 is smaller than that of the case where it is at the reference position. However, at the same time, the source and drain electrodes 13s, 13d of the second drive transistor Tr13 shift rightward relative to the channel protective film 13p, thereby reducing an area of the overlap region 13a, as well as increasing an area of the overlap region 13b, in comparison with the case where they are at the reference position. Therefore, a channel current Ic of the second drive transistor Tr13 is larger than that in the case where the source and drain electrodes 13s, 13d are at the reference position.

Both of the source and drain electrodes 12s, 12d of the first drive transistor Tr12 and the source and drain electrodes 13s, 13d of the second drive transistor Tr13 are formed by patterning a source/drain conductive film. Therefore, a position shift amount of the source electrode and a position shift amount of the drain electrode along an X-axis direction are the same . Accordingly, the sum of areas of the overlap regions 12a, 13a where the channel protective films 12p, 13p overlap the source electrodes 12s, 13s, respectively, is fixed, and the sum of areas of the overlap regions 12b, 13b where the channel protective film 12p, 13p overlap the drain electrodes 12d, 13d, respectively, is fixed. Therefore, the sum of a channel current Ic of the first drive transistor Tr12 and a channel current Ic of the second drive transistor Tr13 is approximately fixed. Even if the source and drain electrodes 12s, 12d, 13s, 13d shift in an up and down direction (a Y-axis direction), both of a length of the channel protective film 12p in a channel width direction and a length of the gate electrode 12g in a channel width direction are sufficiently longer than a length of each of the source and drain electrodes 12s, 12d in a channel width direction in the first drive transistor Tr12. Therefore, an area of each of the overlap regions 12a, 12b is virtually fixed; and in the second drive transistor Tr13, both of a length of the channel protective film 13p in a channel width direction and a length of the gate electrode 13g in a channel width direction are sufficiently longer than a length of each of the source and drain electrodes 12s, 12d in a channel width direction. Therefore, since an area of each of the overlap regions 13a, 13b is virtually fixed, a position shift in a left and right direction (an X-axis direction) has only to be considered. Since the selection transistor Tr11 is driven by a data voltage applied from the data line Ld, the selection transistor Tr11 does not flow a current through the luminescent element 21 as the first and second drive transistors Tr12, Tr13. Therefore, even if the source and drain electrodes shift in an X-axis direction, there is no significant harm effect on a luminance gradation of the luminescent element 21.

In this way, even if positions of the source and drain electrodes 12s, 12d of the first drive transistor Tr12 and the source and drain electrodes 13s, 13d of the second drive transistor Tr13 shift rightward compared to the reference position, the luminescent element 21 can emit light at the same or equivalent luminance as that of the luminescent element 21 in the case where they are at the reference position.

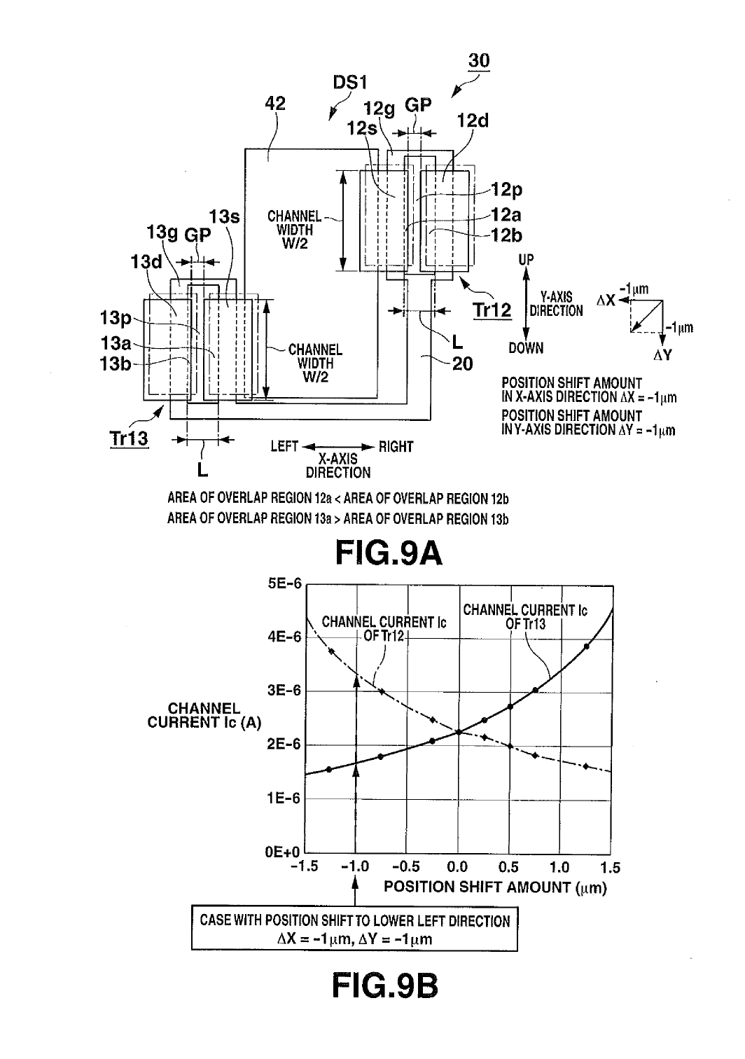

Similarly, as illustrated in FIG. 9A, in the luminescent pixel 30, even if the source and drain electrodes 12s, 12d, 13s, 13d shift in a lower left direction relative to the gate electrodes 12g, 13g (channel protective films 12p, 13p) from the reference position illustrated in FIG. 7A (a position shift amount in an X-axis direction ΔX=a position shift amount in a Y-axis direction ΔY=−1 μm), a channel current Ic that flows through the second drive transistor Tr13 is smaller than that in the case where the second drive transistor Tr13 is at the reference position, as illustrated in FIG. 9B. However, the change of the channel current Ic is offset since a channel current Ic that flows through the first drive transistor Tr12 is larger than that in the case where the first drive transistor Tr12 is at the reference position. Accordingly, the sum of both of the channel currents Ic is 5.1 μm (see FIGS. 10A and 10B), and is approximately equal to that in the case illustrated in FIGS. 7A, 7B and the case illustrated in FIGS. 8A and 8B.

Such a structure shift the source and drain electrodes 12s, 12d of the first drive transistor Tr12 leftward relative to the channel protective film 12p, thereby reducing an area of the overlap region 12a, as well as increasing an area of the overlap region 12b, in comparison with the case where they are at the reference position. Therefore, a channel current Ic of the first drive transistor Tr12 is larger than that of the case of the reference position. However, at the same time, the source and drain electrodes 13s, 13d of the second drive transistor Tr13 shift leftward relative to the channel protective film 13p, an area of the overlap region 13a increases and an area of the overlap region 13b reduces in comparison with the case of the reference position. As a result, a channel current Ic of the second drive transistor Tr13 is smaller than that in the case of the reference position.

In this way, even if positions of the source and drain electrodes 12s, 12d of the first drive transistor Tr12 and the source and drain electrodes 13s, 13d of the second drive transistor Tr13 shift leftward relative to the reference position, the luminescent element 21 can emit light at the same or equivalent luminance as that of the luminescent element 21 in the case of the reference position.

As illustrated in FIGS. 10A and 10B, as a position shift amount of the source and drain electrodes in an X-axis direction is changing as follows: −1 μm, −0.5 μm, 0 μm, 0.5 μm, and 1 μm, a channel current Ic becomes 3.5×10⁻⁶ μA, 4.0×10⁻⁶ μA, 4.6×10⁻⁶ μA, 5.5×10⁻⁶ μA, and 6.9×10⁻⁶ μA, respectively, in the reference example. As a result, the maximum value of a channel current Ic is twice as large as the minimum value thereof within this range. Meanwhile, in the present embodiment, as a position shift amount is changing as the above, a channel current Ic becomes 5.1×10⁻⁶ μA, 4.8×10⁻⁶ μA, 4.6×10⁻⁶ μA, 4.8×10⁻⁶ μA, and 5.1×10⁻⁶ μA, respectively. As a result, the maximum value of a channel current Ic is one point one times the minimum value thereof within this range, and therefore a difference between the maximum and minimum values is small and a channel current Ic maintains an approximately fixed value within a range of ±0.5×10⁻⁶ μA.

As described above, in a pixel drive circuit DS1 according to the present embodiment and a display device using the pixel drive circuit DS1, the first drive transistor Tr12 is connected to one side of the pixel electrode 42, and the second drive transistor Tr13 is connected to the other side opposite to the one side of the pixel electrode 42. Therefore, even if, due to an alignment deviation of a mask for laser irradiation in a photolithography device or an exposure device (a stepper), a position shift of the source and drain electrodes 12s, 12d, 13s, 13d occurs relative to the gate electrodes 12g, 13g or channel protective films 12p, 13p, a reduction of a channel current Ic that flows through the first drive transistor Tr12 can be offset by an increase of a channel current Ic that flows through the second drive transistor Tr13, or an increase of a channel current Ic that flows through the first drive transistor Tr12 can be offset by a reduction of a channel current Ic that flows through the second drive transistor Tr13, thereby making the sum of the channel currents Ic of the first and second drive transistors Tr12, Tr13 can be approximately fixed. By this, a display device having a plurality of luminescent pixels 30 each including a luminescent element 21 as a display element, can emit light having a uniform luminance.

(Second embodiment) A display device according to a second embodiment is different from the display device according to the first embodiment in the following points. In the first embodiment, the pixel drive circuit DS1 has a total of three transistors: one selection transistor Tr11, and two drive transistors, that is, the first and second drive transistors Tr12, Tr13 whereas in the second embodiment a pixel drive circuit DS11 has a total of four transistors: two selection transistors, that is, a first selection transistor Tr51 and a second selection transistor Tr52 and two drive transistors, that is, a first drive transistor Tr53 and a second drive transistor Tr54, and the data line is connected indirectly to one of a source and a drain of the drive transistor, instead of to a gate of the drive transistor. The same portions as those of the first embodiment have identical or corresponding reference letters and numerals and will not be described, unless otherwise noted.

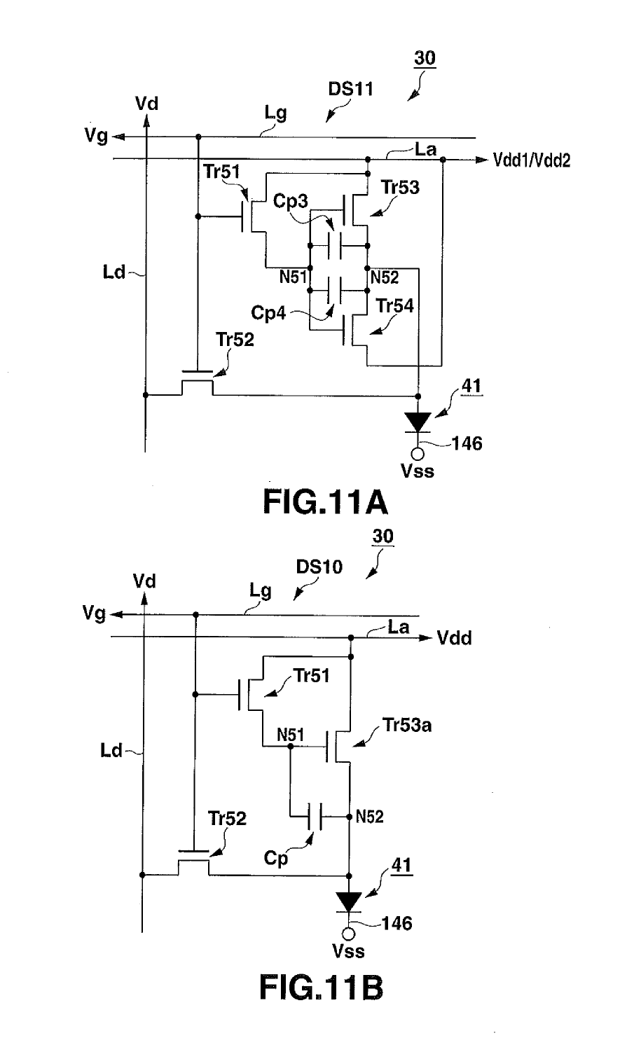

As illustrated in FIG. 11A, each of the luminescent pixels 30 includes a luminescent element 41 such as an organic EL element, and the pixel drive circuit DS11 to activate the luminescent element 41. The pixel circuit substrate includes the substrate 31, pixel drive circuit DS11, and a pixel electrode 142 of the luminescent element 41.

The pixel drive circuit DS11 includes the first and second selection transistors Tr51, Tr52, first and second drive transistors Tr53, Tr54, and capacitors Cp3, Cp4. Each of the first and second selection transistors Tr51, Tr52 and first and second drive transistors Tr53, Tr54 is an inversely-staggered n-channel type thin film transistor (TFT) that includes a semiconductor layer containing amorphous silicon or microcrystal silicon. The capacitors Cp3, Cp4 store, as an electric charge, data for display such as a gradation signal supplied from the data line Ld.

The pixel drive circuit DS11 according to the present embodiment is characterized in including two transistors, that is, the first and second drive transistors Tr53, Tr54 as illustrated in FIG. 11A whereas a pixel drive circuit DS10 according to a reference example illustrated in FIG. 11B is different from the pixel drive circuit DS11 according to the present embodiment in that it has only one drive transistor Tr53a. For comparison, the following description is based on conditions set so that a channel length of the drive transistor Tr53a in the reference example is equal to each of a channel length of the first and second drive transistors Tr53, Tr54 in the present embodiment, and a channel width of the drive transistor Tr53a in the reference example is equal to the sum of each of a channel width of the first and second drive transistors Tr53, Tr54 in the present embodiment.

As illustrated in FIGS. 1 and 11A, an anode line La connected to each of the plurality of pixel drive circuits DS11 arranged in a row direction, the plurality of data lines Ld connected to each of the plurality of pixel drive circuits DS11 arranged in a column direction, and the gate line Lg to select (switch) the first and second selection transistors Tr51, Tr52 of each of the plurality of pixel drive circuits DS11 arranged in a row direction are formed on the substrate 31.

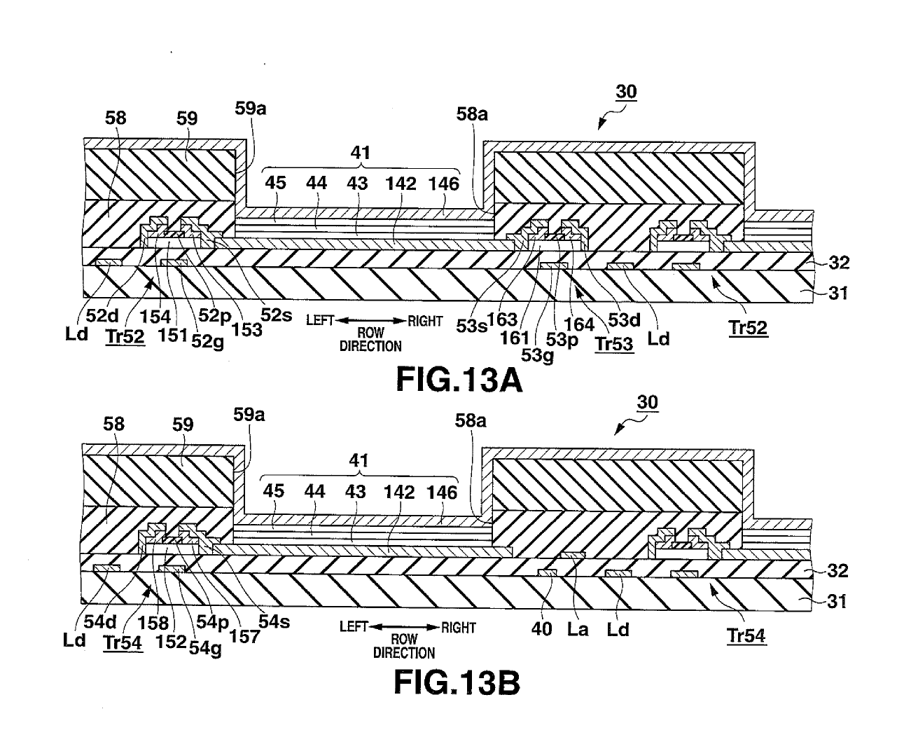

In the pixel drive circuit DS11 according to the present embodiment illustrated in FIG. 11A, in the first selection transistor Tr51, a gate electrode 51g is connected to the gate line Lg, a drain electrode 51d is connected to the anode line La, and a source electrode 51s is connected to a node N51, respectively. In the second selection transistor Tr52, a gate electrode 52g is connected to the gate line Lg, a source electrode 52s is connected to the data line Ld, and a drain electrode 52d is connected to a node N52, respectively. In the first and second drive transistors Tr53, Tr54, gate electrodes 53g, 54g are connected to the node N51, drain electrodes 53d, 54d are connected to the anode line La, and source electrodes 53s, 54s are connected to the node N52, respectively. Both ends of the capacitor Cp3 is connected between the gate electrode 53g and source electrode 53s (nodes N51, N52) of the first drive transistor Tr53. Both ends of the capacitor Cp4 is connected between the gate electrode 54g and source electrode 54s (nodes N51, N52) of the second drive transistor Tr54. The capacitor Cp3 and capacitor Cp4 are set to have the same capacity. Each of these capacitors Cp3, Cp4 is a capacity component that has an auxiliary capacity additionally provided between the gate and source of the first and second drive transistors Tr53, Tr54 or that has a parasitic capacity and an auxiliary capacity between the gate and source of the first and second drive transistors Tr53, Tr54. The node N52 is connected to an anode of the luminescent element 41, and a cathode of the luminescent element 41 is connected to a counter electrode 146. In this way, the first and second drive transistors Tr53, Tr54 are connected in parallel between the anode line La and node N52 (luminescent element 41), and seemingly function as one transistor. The reference voltage Vss is applied to the cathode (counter electrode 146, see FIG. 13) of the luminescent element 41.

In the pixel drive circuit DS10 according to the reference example illustrated in FIG. 11B, in the first selection transistor Tr51, the gate electrode is connected to the gate line Lg, the drain electrode is connected to the anode line La, and the source electrode is connected to the node N51, respectively. In the second selection transistor Tr52, the gate electrode is connected to the gate line Lg, the source electrode is connected to the data line Ld, and the drain electrode is connected to the node N52, respectively. In the drive transistor Tr53a, the gate electrode is connected to the node N51, the drain electrode is connected to the anode line La, and the source electrode is connected to the node N52, respectively. Both ends of a capacitor Cp is respectively connected to the gate electrode and source electrode (nodes N51, N52) of the drive transistor Tr53a. The node N52 is connected to an anode of the luminescent element 41, and a cathode of the luminescent element 41 is connected to the counter electrode 146.

Referring to FIGS. 1, 11A, 12, during a writing period, an electric potential of the anode line La is set to be a first supply voltage Vdd1, an on-level selection signal is output to the gate line Lg to take the first and second selection transistors Tr51, Tr52 into an on-state, and a gradation signal (voltage signal or current signal) is applied to the data line Ld, thereby making a writing current flow through each of the plurality sets of first and second drive transistors Tr53, Tr54 arranged in a row direction via the anode line La in each of the luminescent pixels 30. The writing currents from the first and second drive transistors Tr53, Tr54 converge at the node N52, and then the converged writing current flows through the second selection transistor Tr52 and data line Ld. That is, the sum of the writing current flowing through the first transistor Tr53 and the writing current flowing through the second drive transistor Tr54 is equal to a current value of the writing current that flows through the anode line La, and is also equal to a current value of the writing current that flows through the data line Ld. In this case, a voltage between the gate electrode 53g and source electrode 53s of the first drive transistor Tr53 is set according to a current value of the writing current that flows between the drain electrode 53d and source electrode 53s of the first drive transistor Tr53, and the voltage is stored as an electric charge in the capacitor Cp3. At the same time, a voltage between the gate electrode 54g and source electrode 54s of the second drive transistor Tr54 is set according to a current value of a writing current that flows between the drain electrode 54d and source electrode 54s of the second drive transistor Tr54, and the voltage is stored as an electric charge in the capacitor Cp4. During the writing period, an electric potential (reference voltage Vss) of the counter electrode 146 is less or equal to an electric potential of the first supply voltage Vdd1 and also is less or equal to an electric potential of a gradation signal of the data line Ld. This prevents the writing current from flowing through the luminescent layer 45 of the luminescent element 41, which does not emit light, as a result.

Next, during a display period, an electric potential of the anode line La is set to a second supply voltage Vdd2 that is sufficiently higher than the first supply voltage Vdd1 and reference voltage Vss; an off-level selection signal is output to the gate line Lg to take the first and second selection transistors Tr51, Tr52 into an off-state, thereby preventing the writing current from flowing through the data line Ld. In this case, the capacitor Cp3 continues to apply a voltage to the gate electrode 53g and source electrode 53s so that the first drive transistor Tr53 can flow a drive current with the same current value as that of the writing current flowing during the writing period. At the same time, the capacitor Cp4 continues to apply a voltage to the gate electrode 54g and source electrode 54s so that the second drive transistor Tr54 can flow a drive current with the same current value as that of the writing current flowing during the writing period. Therefore, the current, which has flown from the anode line La and has branched at the node N51 into a drive current of the first drive transistor Tr53 and a drive current of the second drive transistor Tr54, converges at the node N52 and flows through the luminescent element 41, thereby making the luminescent element 41 emit light.

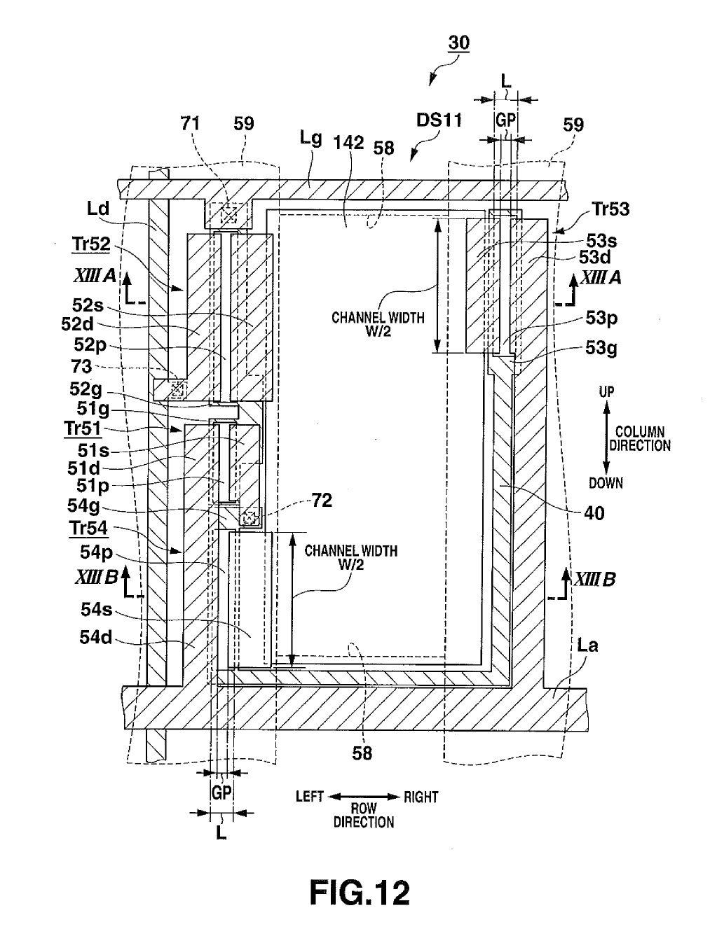

Referring to FIGS. 12, 13A, 13B, on the substrate 31 in each of the luminescent pixel 30, the gate electrodes 51g, 52g of the first and second selection transistors Tr51, Tr52 to select the luminescent element 41, the gate electrodes 53g, 54g of the first and second drive transistors Tr53, Tr54 to supply a drive current to the luminescent element 41, the data line Ld extending along a column direction (up and down direction), and a conductive layer 40 to connect the gate electrodes 51g, 53g to each other are formed. On the substrate 31, the insulating film 32 is formed to cover the data line Ld and gate electrodes 51g to 54g.

Referring to FIGS. 12, 13A, 13B, each of the source electrodes 53s, 54s of the first and second drive transistors Tr53, Tr54 are connected to the pixel electrode 142 on the insulating film 32, each of the drain electrodes 53d, 54d are connected to the anode line La on the substrate 31. Specifically, the source electrode 53s of the first drive transistor Tr53 is connected to one side (right side) of the rectangular pixel electrode 142 (organic EL display element 41), the source electrode 54s of the second drive transistor Tr54 is connected to the other side (left side) opposite to the one side of the pixel electrode 142. The one side and the other side of the pixel electrode 142 is parallel to each other. The gate electrodes 12g, 13g are connected to each other through the conductive layer 40 on the substrate 31. The source electrode 53s and drain electrode 53d of the first drive transistor Tr53 are disposed on the left side and right side, respectively, of a channel protective film 53p in each of the FIGS. 12 and 13A. The source electrode 54s and drain electrode 54d of the second drive transistor Tr54 are disposed on the right side and left side, respectively, of a channel protective film 54p in each of the FIGS. 12 and 13B. Under the source and drain electrodes 53s, 53d of the first drive transistor Tr53, ohmic contact layers 163, 164 that have amorphous silicon containing n-type impurities are formed, respectively. Under the source and drain electrodes 54s, 54d of the second drive transistor Tr54, ohmic contact layers 157, 158 that have amorphous silicon containing n-type impurities are formed, respectively. Under the source and drain electrodes 51s, 51d of the first selection transistor Tr51, ohmic contact layers that have amorphous silicon containing n-type impurities are formed, respectively. Under the source and drain electrodes 52s, 52d of the second selection transistor Tr52, ohmic contact layers 153, 154 that have amorphous silicon containing n-type impurities are formed, respectively. Then, the channel protective film 53p that is a protective insulating film is disposed on a semiconductor layer 161 that contains amorphous silicon or microcrystal silicon, between the source and drain electrodes 53s, 53d, as well as between the ohmic contact layers 163, 164. The channel protective film 54p is disposed on a semiconductor layer 152 that contains amorphous silicon or microcrystal silicon, between the source and drain electrodes 54s, 54d, as well as between the ohmic contact layers 157, 158. A channel protective film 51p of the first selection transistor Tr51 is disposed on a semiconductor layer that contains amorphous silicon or microcrystal silicon, between the source and drain electrodes 51s, 51d, as well as between the ohmic contact layers (not illustrated). A channel protective film 52p of the second selection transistor Tr52 is disposed on a semiconductor layer 151 containing amorphous silicon or microcrystal silicon, between the source and drain electrodes 52s, 52d, as well as between the ohmic contact layers 153, 154. The respective semiconductor layers 151, 152, 161 of the first and second selection transistors Tr51, Tr52 and the first and second drive transistors Tr53, Tr54 are formed on the insulating film 32. The ohmic contact layers 153, 154 are disposed for a low resistance connection between the source and drain electrodes 52s, 52d and the semiconductor layer 151. The ohmic contact layers 163, 164 are disposed for a low resistance connection between the source and drain electrodes 53s, 53d and the semiconductor layer 161. The ohmic contact layers 157, 158 are disposed for a low resistance connection between the source and drain electrodes 54s, 54d and the semiconductor layer 152.

The anode line La and gate line Lg are formed using a source/drain conductive layer for forming the source electrodes 51s, 52s, 53s, 54s and drain electrodes 51d, 52d, 53d, 54d of the respective transistors Tr51, Tr52, Tr53, Tr54. The data line Ld and conductive layer 40 are formed using a gate conductive layer for forming the gate electrodes 51g, 52g, 53g, 54g of the respective transistors Tr51, Tr52, Tr53, Tr54. On the insulating film 32 between the data line Ld and source electrode 52s, a contact portion 73, which is a contact hole to connect the data line Ld and source electrode 52s, is formed. On the insulating film 32 between the gate line Lg and gate electrode 52g, a contact portion 71, which is a contact hole to connect the gate line Lg and gate electrode 52g, is formed. On the insulating film 32 between the source electrode 51s and gate electrode 54g, a contact portion 72, which is a contact hole to connect the source electrode 51s and gate electrode 54g, is formed. These contact portions 71 to 73 properly connect, in a direction of a substrate thickness, with a lower connecting portion formed by patterning the gate conductive layer that becomes the gate electrodes 51g, 52g, 53g, 54g of the first and second selection transistors Tr51, Tr52 and first and second drive transistors Tr53, Tr54, the data line Ld, and the conductive layer 40, with an upper connecting portion formed by pattering the source/drain conductive layer that becomes the source and drain electrodes 51s, 52s, 53s, 54s, 51d, 52d, 53d, 54d of the first and second selection transistors Tr51, Tr52 and first and second drive transistors Tr53, Tr54, the anode line La, and the gate line Lg.

The drive transistor Tr53a in the reference example illustrated in FIG. 11B has a channel width of W (μm) whereas each of the first and second drive transistors Tr53, Tr54 in the present embodiment illustrated in FIG. 11A has a channel width of W/2 (μm). In this way, the sum of the channel widths of the first and second drive transistors Tr53, Tr54 is equal to the channel width W of the drive transistor Tr53a in the reference example (W=W/2+W/2). Channel lengths L of the semiconductor layers 161, 152 of the first and second drive transistors Tr53, Tr54 are equal to each other, and a distance Gp between the source electrode 53s and drain electrode 53d of the first drive transistor Tr53 and a distance Gp between the source electrode 54s and drain electrode 54d of the second drive transistor Tr54 are equal to each other. As described above, the first and second drive transistors Tr53, Tr54, as with the drive transistor Tr53a, are connected between the anode line La and node N12. Therefore, the first and second drive transistors Tr53, Tr54 function as a TFT having a channel width of W (μm), as with the drive transistor Tr53a in the reference example.

As illustrated in FIGS. 13A and 13B, the luminescent element 41 includes the pixel electrode 142 as an anode electrode, the hole injection layer 43, the interlayer 44, the luminescent layer 45, and the counter electrode 146 as a cathode electrode.

These hole injection layer 43, interlayer 44 and luminescent layer 45 become a carrier transportation layer that carries an electron and hole under a predetermined electric field. An interlayer insulating film 58 is a protective film that covers tops of the transistors Tr51, Tr52, Tr53, Tr54, data line Ld, gate line Lg, and anode line La, and also covers the periphery of the pixel electrode 142. In the interlayer insulating film 58, an approximately rectangular opening 58a is formed to define a luminescent region of the luminescent pixel 30. On the interlayer insulating film 58, a stripe-shaped dividing wall 59 is formed extending in a column direction (up and down direction in FIG. 12). The dividing wall 59 has striped-shaped openings 59a corresponding to the plurality of openings 58a along a column direction.

The counter electrode 146 is an electrode layer that faces the pixel electrode 42 of all of the luminescent pixels 30 (luminescent element 41) arranged in a matrix manner on the substrate 31 and also is formed continuously. The counter electrode 146 functions as a common electrode, and to which a predetermined low voltage (a reference voltage Vss (reference electric potential) such as a ground electric potential GND) is commonly applied.

The first drive transistor Tr53 includes the semiconductor layer 161, channel protective film 53p, drain electrode 53d, source electrode 53s, ohmic contact layers 163, 164, gate electrode 53g, and the insulating film 32 between the semiconductor layer 161 and gate electrode 53g. The second drive transistor Tr54 includes the semiconductor layer 152, channel protective film 54p, drain electrode 54d, source electrode 54s, ohmic contact layers 157, 158, gate electrode 54g, and the insulating film 32 between the semiconductor layer 152 and gate electrode 54g. The first selection transistor Tr51 includes the semiconductor layer (not illustrated), channel protective film 51p, drain electrode 51d, source electrode 51s, ohmic contact layers (not illustrated), gate electrode 51g, and the insulating film 32 between the semiconductor layer and gate electrode 51g. The second selection transistor Tr52 includes the semiconductor layer (not illustrated), channel protective film 52p, drain electrode 52d, source electrode 52s, ohmic contact layers (not illustrated), gate electrode 52g, and the insulating film 32 between the semiconductor layer and gate electrode 52g.

According to the present embodiment, in the first drive transistor Tr53, an area of an overlap region 53a of the source electrode 53s and the channel protective film 53p and an area of an overlap regions 53b of the drain electrode 53d and the channel protective film 53p are set to be equal to each other. In the drive transistor Tr54, an area of an overlap region 54a of the source electrode 54s and the channel protective film 54p and an area of an overlap region 54b of the drain electrode 54d and the channel protective film 54p are set to be equal to each other.

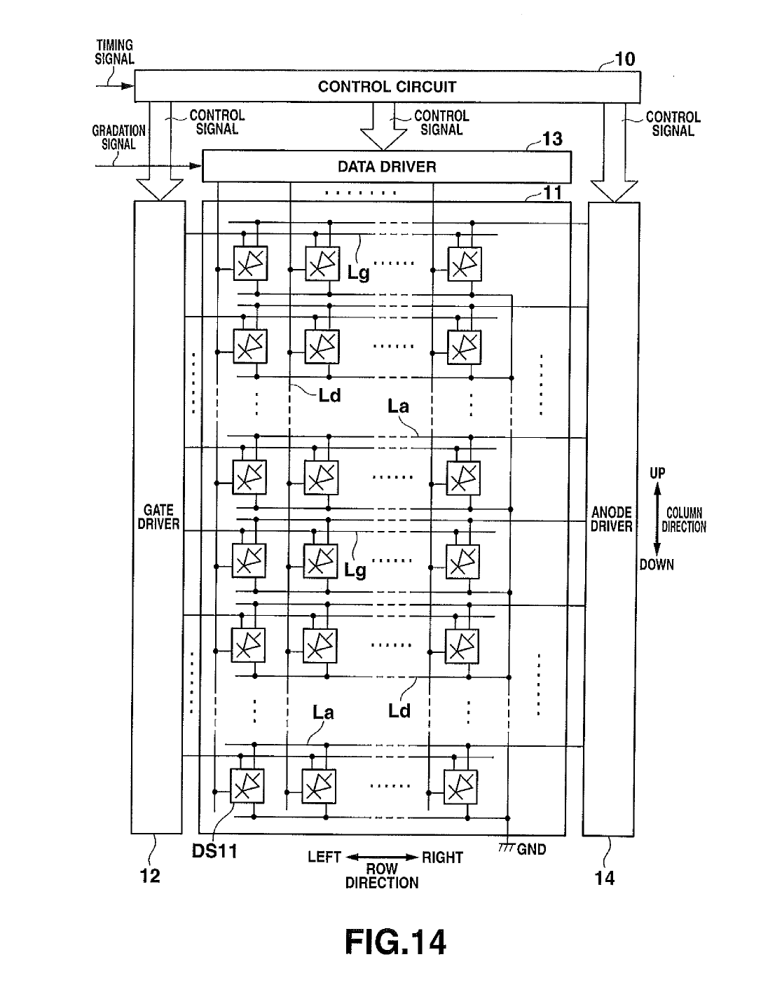

Next, referring to FIGS. 11A and 14, a writing operation and a light-emitting operation of the pixel drive circuit DS11 in the present embodiment will be described. As illustrated in FIG. 14, the gate line Lg is connected to a gate driver 12 disposed on a periphery of the luminescent panel; the data line Ld is connected to a data driver 13 disposed on the periphery of the luminescent panel; and the anode line La (current supply line) is connected to an anode driver 14 as a predetermined high potential power source.

(Writing Operation) As illustrated in FIG. 14, the gate driver 12 outputs a high-level (on-level ON) selection signal sequentially from the first line gate line Lg to the n-th line gate line Lg, according to a group of control signals output from a control circuit 10 based on a timing signal supplied externally, during a writing period (a scanning period). To each of the gate lines Lg, other than a gate line Lg to which an on-level selection signal is output, a low-level (off-level) selection signal is output. According to a group of control signals output from the control circuit 10, the anode driver 14 sets, the anode line La connected to the plurality of luminescent pixels 30 arranged in a row direction that corresponds to a gate line Lg to which an on-level ON selection signal is output, to an electric potential of the first supply voltage Vdd1. According to a group of control signals output from the control circuit 10 based on a gradation signal supplied externally, the data driver 13 applies to all data lines Ld, a gradation voltage having a voltage value less or equal to the reference voltage Vss or a gradation current flowing in a direction pulling from the anode line La into the data driver 13, depending on the gradation signal. An electric potential of the first supply voltage Vdd1 that is set to the anode line La is less or equal to an electric potential of the reference voltage Vss.

In this way, referring to FIG. 11A, during a period when an on-level ON pulse is output to each of the gate lines Lg, the first and second selection transistors Tr51, Tr52 come into on-state. This connects between the gate electrode 53g and drain electrode 53d of the first drive transistor Tr53, as well as between the gate electrode 54g and drain electrode 54d of the second drive transistor Tr54, thereby making the first and second drive transistors Tr53, Tr54 come into a diode-connection state. Then, according to a gradation voltage signal or a gradation current signal that is applied from the data driver 13 to each of the data lines Ld, a writing current flows between the drain and source of each of the first and second drive transistors Tr53, Tr54 via the data line Ld and second selection transistor Tr52. Due to this, a voltage according to a current flowing between the drain electrode 53d and source electrode 53s of the first drive transistor Tr53 is automatically applied to between the gate electrode 53g and source electrode 53s of the first drive transistor Tr53; and a voltage according to a current value of a current flowing between the drain electrode 54d and source electrode 54s of the second drive transistor Tr54 is applied to between the gate electrode 54g and source electrode 54s of the second drive transistor Tr54.

Referring to FIG. 11A, an electric potential of each of the gate electrodes 53g, 54g is equal to each of an electric potential of the drain electrodes 54d, 54g in the first and second drive transistors Tr53, Tr54. To each of the data lines Ld, a gradation signal of a gradation voltage or a gradation current is applied from the data driver 13. This generates an electric potential difference between the gate and source of each of the first and second drive transistors Tr53, Tr54, making a current I with a current value flow according to the gradation signal. During a scanning period, an electric potential of the anode line La is less or equal to the reference voltage Vss. Due to this, an electric potential of an anode of the luminescent element 41 is less or equal to an electric potential of a cathode of the luminescent element 41, that is, a zero voltage or a reverse bias voltage is applied to the luminescent element 41. Therefore, a current from the anode line La does not flow to the luminescent element 41.

At this time, based on a gradation voltage or a gradation current applied from the data driver 13 according to a luminance gradation value of image data, a voltage at both ends of the capacitor Cp3 of the luminescent pixel 30 is a voltage according to a current value of a channel current Ic flowing from the drain electrode 53d to the source electrode 53s of the first drive transistor Tr53, and a voltage at the both ends of the capacitor Cp4 is a voltage according to a current value of a channel current Ic flowing from the drain electrode 54d to the source electrode 54d of the second drive transistor Tr54. That is, an electric current charged to each of the capacitors Cp3, Cp4 of the luminescent pixel 30 is an electric current that generates an electric potential difference between the gate and source of the first and second drive transistors Tr53, Tr54 that is required to make a channel current Ic according to image data flow between the drain and source of the first and second drive transistors Tr53, Tr54 of the luminescent element 41.

(Light-emitting Operation) During a display period after a writing period, a selection signal output from the gate driver 12 to a predetermined line of the gate lines Lg is switched from on-level ON to off-level OFF, and then the anode driver 14 of the predetermined line switches an electric potential of the anode line La from the first supply voltage Vdd1 to the second supply voltage Vdd2. Due to this, in the luminescent pixel 30 connected to the predetermined line of the gate line Lg, the gate of the first selection transistor Tr51 and the gate of the second selection transistor Tr52 come into off-state; and the second supply voltage Vdd2 is supplied through the anode line La of the predetermined line to the drain electrode 53d of the first drive transistor Tr53 and the drain electrode 54d of the second drive transistor Tr54.

Referring to FIG. 11A, due to this, the second selection transistor Tr52 of a line in a non-selected state comes into off-state, thereby preventing a current from flowing to the second selection transistor Tr52. In addition, the first selection transistor Tr51 comes into off-state, each of the capacitors Cp3, Cp4 continues to hold an electric charge charged from one end and the other end thereof, and the first and second drive transistors Tr53, Tr54 continue to be in on-state. That is, a voltage value Vgs between the gate and source of each of the first and second drive transistors Tr53, Tr54 is hold. Therefore, even during a display period, each of the first and second drive transistors Tr53, Tr54 continues to flow a current with a current value according to image data. Accordingly, a current value of a channel current Ic that each of the first and second drive transistors Tr53, Tr54 flows during a display period is virtually equal to a current value of a channel current Ic that each of the first and second drive transistors Tr53, Tr54 flows during a writing period. During a display period, a channel current Ic that flows through the first drive transistor Tr53 and a channel current Ic that flows through the second drive transistors Tr54 converge at the node N52, and then flows to the luminescent element 41 which emits light at a luminance according to the sum of current values of both of the channel currents Ic. In this way, the luminescent element 41 emits light at a luminance gradation according to image data.

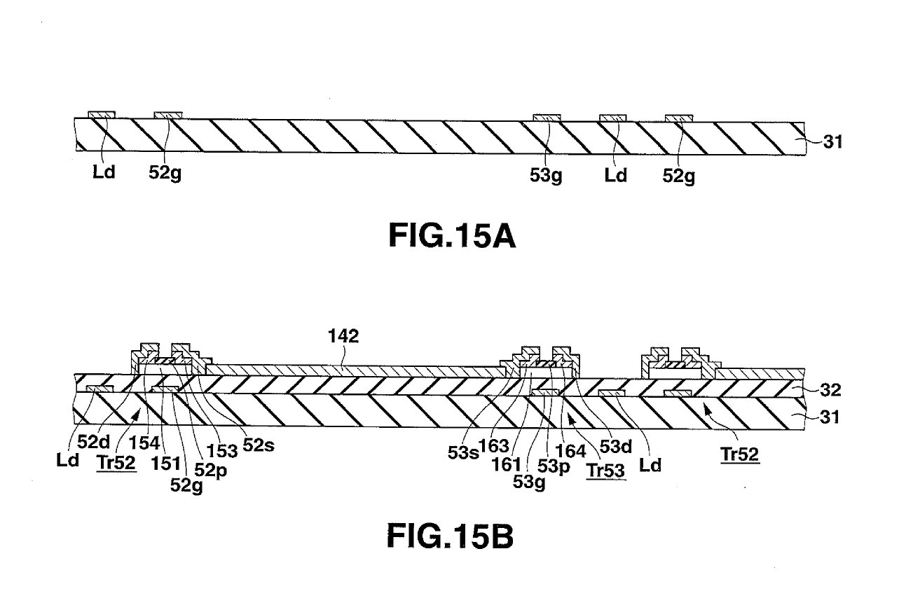

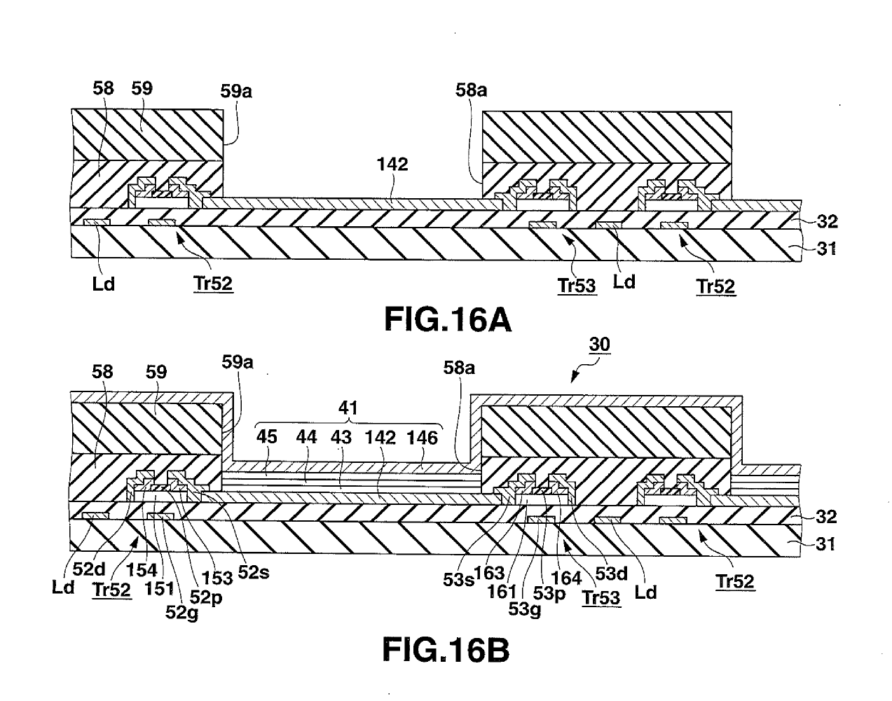

Next, a method for manufacturing a display device according to the present embodiment will be described with reference to FIGS. 15 and 16. In this embodiment, the first selection transistor Tr51 and second drive transistor Tr54 are formed in the same process as that of the second selection transistor Tr52 and first drive transistor Tr53. Therefore, a part of the method for forming the first selection transistor Tr51 and second drive transistor Tr54 will not be described since it has been described regarding a method for forming the second selection transistor Tr52 and first drive transistor Tr53.

First, as illustrated in FIG. 15A, on the substrate 31 that is a luminescent pixel substrate, a gate conductive film containing at least one of, e.g. an Mo film, a Cr film, an Al film, a Cr/AL laminated film, an AlTi alloy film or AlNdTi alloy film, and an MoNb alloy film is formed by a sputtering method or a vacuum deposition method. Then, this is subjected to patterning by photolithography to form the gate electrodes 52g, 53g of the transistors Tr52, Tr53, and the data line Ld. At this time, the gate electrodes 51g, 54g of the transistors Tr51, Tr54 and the conductive layer 40 are also formed although they are not illustrated in FIG. 15A.

Next, as illustrated in FIG. 15B, the insulating film 32, having an insulating material such as a silicon dioxide film and a silicon nitride film, is formed on the gate electrodes 52g, 53g and data line Ld by, e.g. a chemical vapor deposition (CVD) method.

Next, on the insulating film 32, an amorphous silicon layer that becomes a semiconductor layer, and an insulating layer, such as a silicon dioxide film and a silicon nitride film, that becomes a channel protective film, are continuously laminated by, e.g. a CVD method. Then, the insulating layer is subjected to patterning with the use of a resist mask by photolithography to form the channel protective films 52p, 53p. Next, an amorphous silicon layer containing n-type impurities is deposited, and subsequently outer circumferences of the ohmic contact layers 153, 154, 163, 164 of the transistors Tr52, Tr53 are patterned with the use of a resist mask by photolithography. Continuously, the lower amorphous silicon layer is subjected to etching to pattern the semiconductor layers 152, 161 of the transistor Tr52, Tr53. At this time, a channel length L of each of the semiconductor layers 152, 161 of the transistors Tr52, Tr53 is defined by a length in a row direction (X-axis direction) of each of the channel protective films 52p, 53p of the transistors Tr52, Tr53, and is always fixed regardless of a position shift.

Next, by, e.g. a sputtering method and a vacuum deposition method, on the insulating film 32, a transparent conductive film such as ITO is formed and subjected to patterning with the use of a resist mask by photolithography to form the pixel electrode 142.

Then, on the insulating film 32, the contact portions 71 to 73 that are contact holes are formed. After that, a source/drain conductive film containing at least one of, e.g. an Mo film, a Cr film, an Al film, a Cr/Al laminated layer film, an AlTi alloy film or AlNdTi alloy film, and an MoNb alloy film is deposited by, e.g. a sputtering method or a vacuum deposition method, and embedded into the contact portions 71 to 73. After that, the source/drain conductive film is subjected to patterning with the use of a resist mask by photolithography to form the source and drain electrodes 52s, 52d, 53s, 53d of the second selection transistor Tr52 and first drive transistor Tr53, the anode line La and the gate line Lg, and also the ohmic contact layers that are under the source and drain electrodes of the transistors Tr52, Tr53 and between the source and drain electrodes of the transistors Tr52, Tr53 are subjected to etching to form the ohmic contact layers 153, 154, 163, 164 of the transistors Tr52, Tr53.

In this way, each of the gate conductive film, channel protective film, source/drain conductive film is independently subjected to patterning with the use of a resist mask by separated photolithography. Therefore, a relative position shift of the source and drain electrodes may occur. Since the source and drain electrodes of each of the first selection transistor Tr51, second selection transistor Tr52, first drive transistor Tr53 and second drive transistor Tr54 are formed in the same photolithography process, their degrees of a position shift are the same. Therefore, a distance Gp between the source electrode 53s and drain electrode 53d of the first drive transistor Tr53 and a distance Gp between the source electrode 54s and drain electrode 54d of the second drive transistor Tr54 is always fixed even if a position shift occurs. A relative position shift of each of the source and drain electrodes 53s, 53d, 54s, 54d of the first drive transistor Tr53 and second drive transistor Tr54 is equal to a relative position shift of each of the corresponding gate electrodes 53g, 54g, and also equal to a relative position shift of each of the corresponding channel protective films 53p, 54p. The source electrode 53s of the first drive transistor Tr53 and the source electrode 54s of the second drive transistor Tr54 are formed to connect to overlap the right side and left side, respectively, of two sides of the pixel electrode 42 that are along a column direction and orthogonal to a row direction (see FIG. 12).

Next, as illustrated in FIG. 16A, the interlayer insulating film 58 having a silicon nitride film is formed to cover tops of the transistors Tr52, Tr53 and data line Ld by, e.g. a CVD method. After that, on the interlayer insulating film 58, the opening 58a is formed with the use of a resist mask by photolithography. Next, photoactive polyimide is applied to cover the interlayer insulating film 58 and is subjected to patterning by exposure and development with the use of a mask to form the dividing wall 59 having the opening 59a.

After that, as illustrated in FIG. 16B, by using a nozzle printing device that flows a continuous liquid flow or an inkjet device that ejects a plurality of separate liquid droplets, an organic-compound-containing liquid that contains a hole injection material is selectively applied onto the pixel electrode 142 surrounded by the opening 58a. Then, the substrate 31 is heated under an air atmosphere to volatilize a solvent of the organic-compound-containing liquid that contains an organic high-molecular hole injection and transportation material, thereby forming the hole injection layer 43.

Next, with the use of a nozzle printing device or an inkjet device, an organic-compound-containing liquid containing a material that becomes the interlayer 44 is applied onto the hole injection layer 43 and is subjected to drying by heating in a nitrogen atmosphere or in vacuum, thereby removing a residual solvent to form the interlayer 44.

Next, an organic-compound-containing liquid in which a luminescent polymer material (R, G, B) such as a conjugated double bond polymer, e.g. polyparaphenylene vinylene series and polyfluorene series is solved in an organic solvent such as tetralin, tetramethylbenzene, mesitylene, and xylene, by using a nozzle printing device or an inkjet device is subjected to heating in a nitrogen atmosphere, thereby removing a residual organic solvent to form the luminescent layer 45.

After that, as illustrated in FIG. 16B, on the substrate 31 on which the luminescent layer 45 has been formed, the counter electrode 146, which has a two-layer structure composed of a layer having a material with a low work function such as Li, Mg, Ca, Ba and a light reflective conductive layer such as Al, is formed by using vacuum deposition or sputtering.

A working effect of the display device according to the present embodiment is the same as a working effect of the display device according to the first embodiment described with reference to FIGS. 7 to 10. That is, in the pixel drive circuit DS11, according to the present embodiment, and a display device using the pixel drive circuit DS11, the source electrode 53s of the first drive transistor Tr53 is connected to one side of the pixel electrode 142; and the source electrode 54s of the second drive transistor Tr54 is connected to the other side opposite to the one side of the pixel electrode 142. That is, a set of the source and drain electrodes 53s, 53d of the first drive transistor Tr53 and a set of the source and drain electrodes 54s, 54d of the second drive transistor Tr54 are mirror symmetry to each other relative to the pixel electrode 142.

Therefore, even if, due to, e.g. an alignment deviation of a mask for laser irradiation in a photolithography device, position shifts of the source and drain electrodes 53s, 53d, 54s, 54d occur relative to the gate electrodes 53g, 54g or channel protective films 53p, 54p, and as a result, a channel current Ic of one of the first and second drive transistors Tr53, Tr54 increases or reduces, the other transistor reduces or increases a channel current Ic, thereby mitigating a change of the channel current. Accordingly, the sum of the channel currents Ic of the first and second drive transistors Tr53, Tr54 is approximately fixed and light can be emitted at the same or equivalent degree of luminance as the luminance of the luminescent element 41 at the reference position.

On one side (left side) of the pixel electrode 142, the first selection transistor Tr51 or second selection transistor Tr52 is disposed. Thus, it is difficult for the second drive transistor Tr54 disposed on one side of the pixel electrode 142 to dispose on the center portion of one side of the pixel electrode 142, and therefore the second drive transistor Tr54 is connected to the pixel electrode 142 at the back portion (lower left portion) of the one side of the pixel electrode 142. Accordingly, it is more difficult for a drive current from the second drive transistor Tr54 to flow to a front portion (upper left portion) of the one side compared to the back portion of the one side, which may lead to ununiformity on the luminescent layer 45 on the pixel electrode 142. However, since the first drive transistor Tr53 on the other side opposite to the one side is disposed, facing the first selection transistor Tr51 or second selection transistor Tr52 (front portion), not the second drive transistor Tr54 (back portion), that is, on the front portion of the other side (upper left portion), the first drive transistor Tr53 and second drive transistor Tr54 can uniformly flow an electric current through an entire region of the pixel electrode 42, thereby enabling an entire region of the luminescent layer 45 on the pixel electrode 42 to emit light.

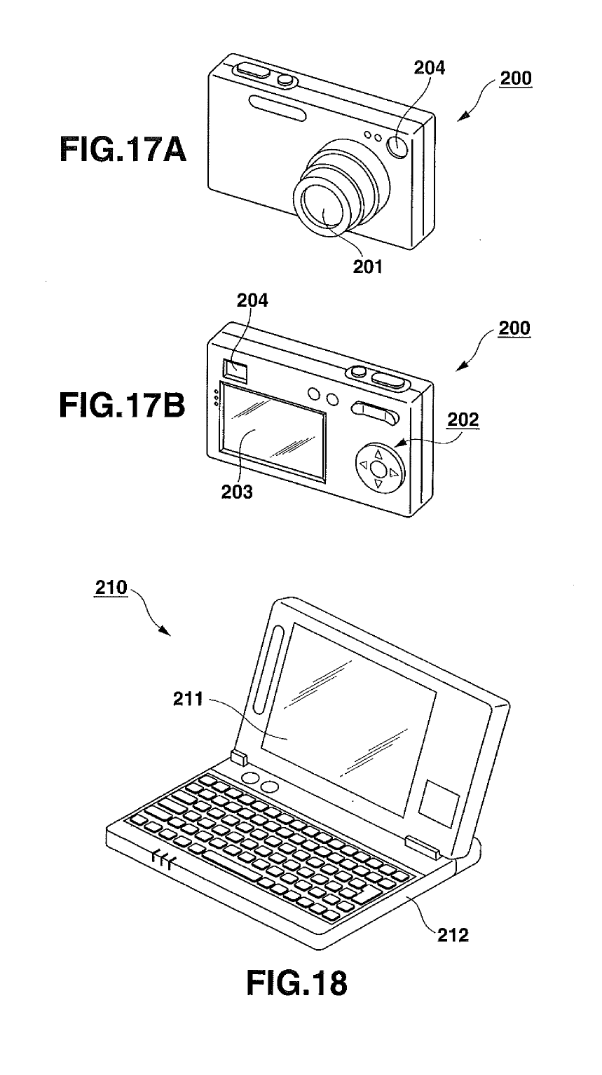

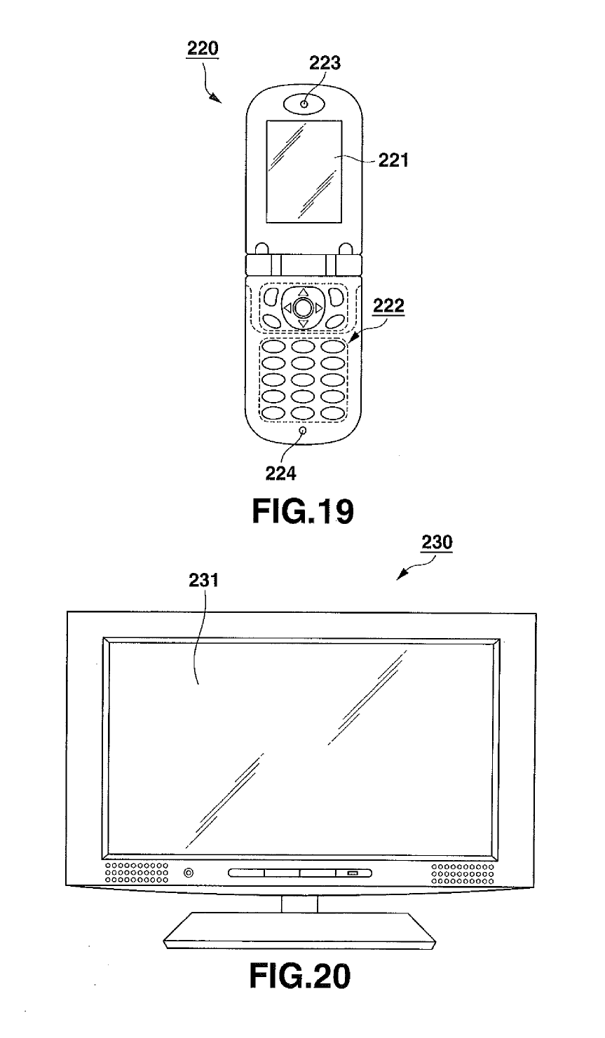

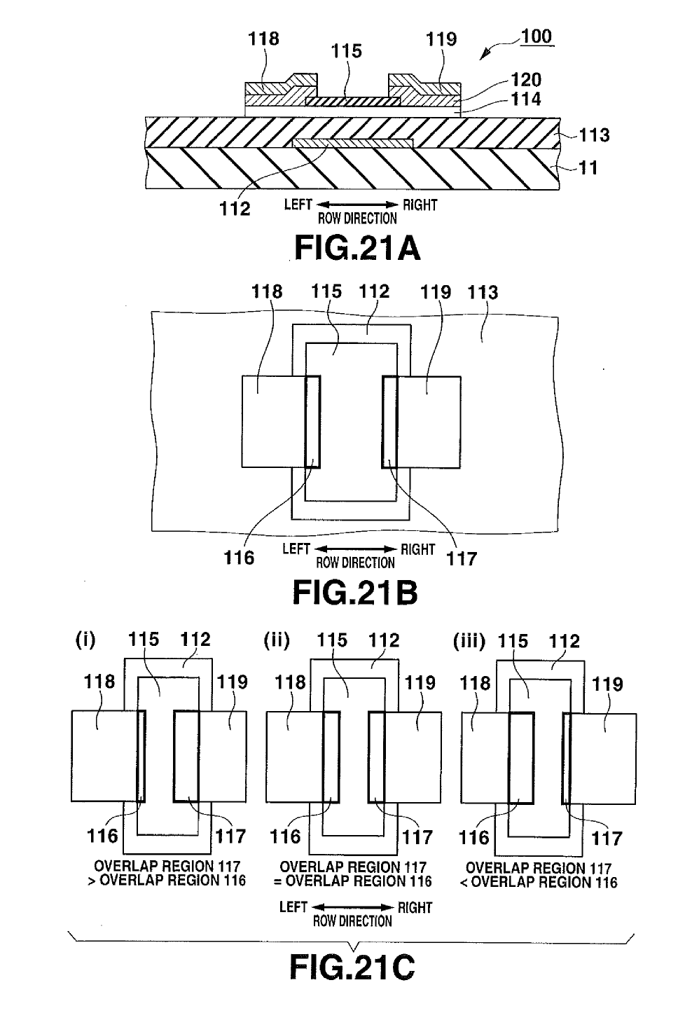

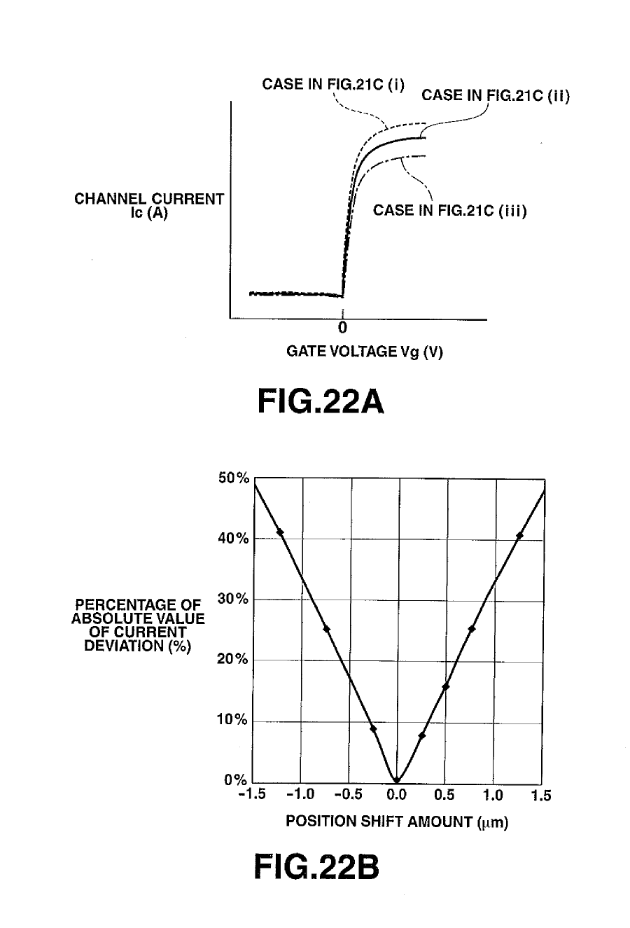

The display device according to each of the embodiments can be incorporated to an electronic equipment such as a digital camera illustrated in FIGS. 17A, 17B, a personal computer illustrated in FIG. 18, a cell phone illustrated in FIG. 19, and a television device (TV) illustrated in FIG. 20.

As illustrated in FIGS. 17A, 17B, a digital camera 200 includes a lens portion 201, an operation portion 202, a display portion 203, and a finder 204. For this display portion 203, a display device in the above embodiment is used.

A personal computer 210 illustrated in FIG. 18 includes a display portion 211 and an operation portion 212. For this display portion 211, a display device in the above embodiment is used.

A cell phone 220 illustrated in FIG. 19 includes a display portion 221, an operation portion 222, a receiver 223, and a micropohone 224. For this display portion 221, a display device in the above embodiment is used.

A television device 230 illustrated in FIG. 20 includes a display portion 231. For this display portion 231, a display device in the above embodiment is used.

Having described and illustrated the principles of this application by reference to preferred embodiments, it should be apparent that the preferred embodiments may be modified in arrangement and detail without departing from the principles disclosed herein and that it is intended that the application be construed as including all such modifications and variations insofar as they come within the spirit and scope of the subject matter disclosed herein.

For example, in each of the aforementioned embodiments, a display device using an organic EL element for a display device has been described. However, a display element in a display device is not limited to this, but may be other display element such as a light-emitting diode (LED), a field emission display (FED), and plasma display panel (PDP).

In each of the aforementioned embodiments, a structure in which an organic EL element has three layers: a hole injection layer, an interlayer, and a luminescent layer has been described as an example. However, the structure is not limited to this, but may be a two-layer structure of a hole injection layer and a luminescent layer, a single-layer structure in which a luminescent layer also functions as a hole injection layer, or a multilayer structure having four or more layers.

In each of the aforementioned embodiments, a case where a transistor is inversely-staggered has been described as an example. However, the transistor is not limited to this, but may be a coplanar type transistor. In each of the aforementioned embodiments, a semiconductor layer containing amorphous silicon or microcrystal silicon has been described as an example. However, the semiconductor layer is not limited to this, but may have a transistor which includes semiconductor layer containing polysilicon. The transistor is not limited to an n-channel type transistor, but may be a p-channel type transistor. In this case, in each of the embodiments, a source electrode becomes a drain electrode, the drain electrode becomes a source electrode, and a high-level or low-level of a signal output to a gate electrode of the transistor is other way around.

In each of the aforementioned embodiments, a MOS transistor is used. However, the transistor is not limited to this, and may be a transistor formed by a plurality of patterning, such as a diode and a metal-insulator-metal (MIM) element.

In each of the aforementioned embodiments, channel widths of two drive transistors within one pixel drive circuit are equal to each other. However, the channel width is not limited to this, and even if both channel widths may not be necessarily equal to each other, a current deviation can be improved according to a technical idea of the present invention.

In each of the aforementioned embodiments, one drive transistor is disposed on the left and on the right of a pixel electrode within one pixel drive circuit, respectively. However, disposition of the transistor is not limited to this, and, instead of this, one drive transistor may be disposed on the front (upper side) and on the back (lower side) on the pixel electrode, respectively.

In each of the aforementioned embodiments, two drive transistors make one organic EL element emit light. However, the number of transistors is not limited to this, and in a complementary structure, may be three or more, for example, in which two drive transistors each having a channel width of W/4 are connected in parallel, instead of a second drive transistor Tr13 illustrated in FIG. 3.

A pixel drive circuit having three or four transistors has been described as an example. However, the pixel drive circuit is not limited to this, and may have five or more transistors.

In each of the aforementioned embodiments, a pixel structure is a stripe alignment, in which three luminescent pixels emitting three colors, each emitting red (R), green (G) or blue (B) are configured to be one set and arranged in such a way that the same color are arranged in a longitudinal direction. However, the pixel structure is not limited to this, and may be a delta alignment in which each of the three luminescent pixels emitting three colors, each emitting red (R), green (G) or blue (B), has a gravity center at a vertex of a triangle.

In each of the aforementioned embodiments, a position shift of source and drain electrodes of a transistor relative to a channel protective film has mainly be described. However, application of the present invention is not limited to this, and a technical idea of the present invention can be applied to a transistor without a channel protective film, as long as the transistor has a structure in which a position shift (patterning deviation) of a semiconductor layer and source and drain electrodes may occur, for example, a structure in which each of a semiconductor layer and source and drain electrodes is formed by separate patterning by photolithography.

What is claimed is:

1. A pixel circuit substrate comprising:
a pixel electrode;
a first drive element connected to one side of the pixel electrode; and
a second drive element that is connected to the first drive element in parallel and also connected to the other side opposite to the one side of the pixel electrode.

2. The pixel circuit substrate according to claim 1, wherein the first drive element and the second drive element are drive transistors, each having a gate electrode, a semiconductor layer, a source electrode, and a drain electrode.

3. The pixel circuit substrate according to claim 2, wherein the source electrode and drain electrode of the first drive element and the source electrode and drain electrode of the second drive element are minor symmetry to each other relative to the pixel electrode.

4. The pixel circuit substrate according to claim 2,
wherein one of the source electrode of the first drive element and the drain electrode of the first drive element is connected to the one side of the pixel electrode; and
wherein one of the source electrode of the second drive element and the drain electrode of the second drive element is connected to the other side of the pixel electrode.

5. The pixel circuit substrate according to claim 4,
wherein the other of the source electrode of the first drive element and the drain electrode of the first drive element is connected to an anode line,
wherein the other of the source electrode of the second drive element and the drain electrode of the second drive element is connected to the anode line.

6. The pixel circuit substrate according to claim 2,
wherein each of the first drive element and the second drive element further has a channel protective film disposed between the semiconductor layer and the source and drain electrodes.

7. The pixel circuit substrate according to claim 1, wherein the one side and the other side of the pixel electrode are parallel to each other.

8. The pixel circuit substrate according to claim 1, further comprising a switching element to switch the first drive element and the second drive element.

9. The pixel circuit substrate according to claim 8, wherein the switching element is a transistor having a gate electrode connected to a gate line.

10. The pixel circuit substrate according to claim 8,
wherein the switching element is disposed on the other side of the pixel electrode,
wherein the first drive element is disposed on the one side of the pixel electrode and, not facing the second drive element, but facing the switching element.

11. The pixel circuit substrate according to claim 2,
further comprising a switching element that has a gate electrode, a source electrode, and a drain electrode, and switches the first drive element and the second drive element,
wherein, in the switching element, one of the source and drain electrodes is connected to a data line, the other of the source and drain electrodes is connected to the gate electrode of the first drive element and the gate electrode of the second drive element.

12. The pixel circuit substrate according to claim 2,
further comprising a first switching element and a second switching element, each having a gate electrode, a source electrode and a drain electrode,
wherein, in the first switching element, one of the source and drain electrodes is connected to the gate electrode of the first drive element and the gate electrode of the second drive element,
wherein, in the second switching element, one of the source and drain electrodes is connected to the source electrode of the first drive element and the source electrode of the second drive element, or the drain electrode of the first drive element and the drain electrode of the second drive element.

13. A display device comprising:
the pixel circuit substrate according to claim 1;
a counter electrode; and
a luminescent layer disposed between the pixel electrode and the counter electrode.

14. An electronic equipment comprising the display device according to claim 13.

15. A method for manufacturing a pixel circuit substrate, comprising:
forming a pixel electrode; and
forming a first drive element connected to one side of the pixel electrode, and a second drive element that is connected to the first drive element in parallel and also is connected to the other side opposite to the one side of the pixel electrode.

16. The method for manufacturing a pixel circuit substrate according to claim 15, wherein the first drive element and the second drive element are drive transistors, each having a gate electrode, a semiconductor layer, a source electrode, and a drain electrode.

17. The method for manufacturing a pixel circuit substrate according to claim 16, further comprising:
forming the semiconductor layer of the first drive element and the semiconductor layer of the second drive element by patterning with the use of a first resist mask, and
forming the source and drain electrodes of the first drive element and the source and drain electrodes of the second drive element by patterning with the use of a second resist mask different from the first resist mask.

18. The method for manufacturing a pixel circuit substrate according to claim 17,
wherein each of the first drive element and the second drive element has a channel protective film disposed between the semiconductor layer and the source and drain electrodes, and
further comprising forming the channel protective film of the first drive element and the channel protective film of the second drive element with the use of a third resist mask different from the first resist mask and second resist mask.
